(19) United States
(12) Patent Application Publication
(10) Pub. No.: US 2025/0008777 A1
(43) Pub. Date: Jan. 2, 2025

(54) DISPLAY PANEL, ELECTRONIC APPARATUS INCLUDING THE SAME, AND METHOD FOR MANUFACTURING THE DISPLAY PANEL

(71) Applicant: Samsung Display Co., Ltd., Yongin-si (KR)

(72) Inventors: HYUNEOK SHIN, Yongin-si (KR); BYUNG SOO SO, Yongin-si (KR)

(73) Assignee: Samsung Display Co., Ltd., Yongin-si (KR)

(21) Appl. No.: 18/616,610

(22) Filed: Mar. 26, 2024

(30) Foreign Application Priority Data
Jun. 27, 2023 (KR) 10-2023-0082974

(51) Int. Cl. H10K 59/122; H10K 59/12; H10K 59/80

(52) U.S. Cl. CPC H10K 59/122; H10K 59/1201; H10K 59/873

(57) ABSTRACT

A display panel includes a base layer, a pixel defining layer in which a light-emitting opening is defined, a partition wall in which a partition wall opening corresponding to the light-emitting opening is defined, and a light-emitting element including an anode, an intermediate layer, and a cathode that is in contact with the partition wall. The partition wall includes a first partition wall layer including transparent conductive oxide and a second partition wall layer including a metal or silicon-based compound. The first partition wall layer includes a first portion, a second portion spaced apart from the pixel defining layer and having a height difference with respect to the first portion, and a first side portion that connects the first portion and the second portion.

### CROSS-REFERENCE TO RELATED APPLICATIONS

This U.S. non-provisional patent application claims priority to and benefits of Korean Patent Application No. 10-2023-0082974 under 35 U.S.C. § 119, filed on Jun. 27, 2023 in the Korean Intellectual Property Office (KIPO), the entire contents of which are hereby incorporated by reference.

### BACKGROUND

The disclosure herein relates to a display panel, an electronic apparatus including the same, and a method for manufacturing the display panel, and more particularly, to a display panel having an improved transmittance, an electronic apparatus including the same, and a method for manufacturing the display panel.

Display devices such as televisions, monitors, smart phones, and tablets that provide images to a user include display panels that display images. Various display panels such as liquid crystal display panels, organic light-emitting display panels, electro wetting display panels, and electrophoretic display panels are being developed as the display panel.

An organic light-emitting display panel may include an anode, a cathode, and an emission pattern. The emission pattern may be separated for each emission area, and the cathode may provide a common voltage to each emission area.

### SUMMARY

The disclosure provides a display panel having an improved transmittance of an optical signal.

The disclosure also provides an electronic apparatus having an improved transmittance of an optical signal.

The disclosure also provides a method for manufacturing a display panel having improved reliability.

The technical objectives to be achieved by the disclosure are not limited to those described herein, and other technical objectives that are not mentioned herein would be clearly understood by a person skilled in the art from the description of the disclosure.

An embodiment of the disclosure provides a display panel including a base layer; a pixel defining layer which is disposed on the base layer and in which a light-emitting opening is defined; a partition wall which is disposed on the pixel defining layer and in which a partition wall opening corresponding to the light-emitting opening is defined; and a light-emitting element including an anode, an intermediate layer, and a cathode that is in contact with the partition wall, the light-emitting element being disposed in the partition wall opening, wherein the partition wall includes a first partition wall layer disposed on the pixel defining layer and including transparent conductive oxide; and a second partition wall layer disposed on the first partition wall layer and including a metal or silicon-based compound, wherein the first partition wall layer includes a first portion disposed on the pixel defining layer; a second portion spaced apart from the pixel defining layer and having a height difference with respect to the first portion; and a first side portion that connects the first portion and the second portion.

In an embodiment, the partition wall opening may include a first area in which the light-emitting element is disposed; and a second area having a width less than a width of the first area, wherein the first side portion of the first partition wall layer may include a first outer surface that defines the first area, and the second portion of the first partition wall layer may include a second outer surface configured to define the second area.

In an embodiment, the cathode may be in contact with the first side portion of the first partition wall layer.

In an embodiment, the partition wall may further include an organic film disposed between the first partition wall layer and the second partition wall layer.

In an embodiment, the first portion of the first partition wall layer may be directly disposed on the pixel defining layer.

In an embodiment, a gap defined by the first portion, the first side portion, and a portion of the second partition wall layer may be defined in the partition wall, and the organic film may be disposed to be filled into the gap.

In an embodiment, the second partition wall layer may be disposed on the first portion and the organic film.

In an embodiment, an outer surface of the second portion and an outer surface of the second partition wall layer may define an alignment surface.

In an embodiment, the second partition wall layer may be directly disposed on the first partition wall layer.

In an embodiment, the second partition wall layer may include a third portion disposed on the first portion; a fourth portion spaced apart from the first portion and having a height difference with respect to the third portion; and a second side portion configured to connect the third portion to the fourth portion.

In an embodiment, the first partition wall layer may include at least one of indium tin oxide, indium zinc oxide, zinc oxide, indium zinc tin oxide, and indium oxide.

In an embodiment, the second partition wall layer may include at least one of silicon oxide, silicon nitride, and silicon oxynitride.

In an embodiment, each of the first portion and the second portion may have a thickness of about 1,000 Å or more and about 2,000 Å or less, and the second partition wall layer may have a thickness of about 1,000 Å or more and about 2,000 Å or less.

In an embodiment, the display panel may further include a sacrificial pattern which is disposed between the anode and the pixel defining layer and in which a sacrificial opening overlapping the light-emitting opening is defined.

In an embodiment, the display panel may further include a thin film encapsulation layer disposed on the light-emitting element and including a plurality of thin films, wherein the thin film encapsulation layer may include an encapsulation inorganic pattern which covers the light-emitting element and of which a portion is in contact with the partition wall.

In an embodiment of the disclosure, an electronic apparatus includes a display device including a display area including a first area, through which an optical signal passes, and a second area adjacent to the first area; and a non-display area adjacent to the display area; and an electronic module disposed below the display device to overlap the first area and receiving the optical signal, wherein the display device includes a base layer; a partition wall which is disposed on the base layer and in which a partition wall opening is defined; a light-emitting element including an anode, an intermediate layer, and a cathode that is in contact with the partition wall, the light-emitting element being disposed in the partition wall opening, wherein the partition wall includes a first partition wall layer disposed on the base layer and including transparent conductive oxide; a second partition wall layer disposed on the first partition wall layer and including a metal or silicon-based compound; and an organic film disposed between the first partition wall layer and the second partition wall layer.

In an embodiment of the disclosure, a method for manufacturing a display panel includes providing a preliminary display panel including a base layer, an anode disposed on the base layer, and a preliminary pixel defining layer disposed on the base layer to cover the anode; forming an inorganic film in which an opening through which a top surface of the preliminary pixel defining layer is exposed is defined, on the preliminary display panel; forming a first preliminary partition wall layer that overlaps at least the opening and comprises transparent conductive oxide; forming a second preliminary partition wall layer including a metal or silicon-based compound on the first preliminary partition wall layer; forming a photoresist pattern overlapping the opening on the second preliminary partition wall layer; etching the inorganic film, the first preliminary partition wall layer, and the second preliminary partition wall layer using the photoresist pattern as a mask to form a partition wall in which a partition wall opening overlapping the anode is defined; and forming a light-emitting pattern and a cathode that is in contact with the partition wall in the partition wall opening.

In an embodiment, the forming of the partition wall may include primarily etching the inorganic film, the first preliminary partition wall layer, and the second preliminary partition wall layer; and secondarily etching the inorganic film, and in the secondarily etching of the inorganic film, the inorganic film may be removed.

In an embodiment, in the forming of the partition wall, a first partition wall layer and a second partition wall layer may be formed, the first partition wall layer may include a first portion adjacent to the base layer; a second portion spaced apart from the base layer and having a height difference with respect to the first portion; and a first side portion connecting the first portion to the second portion, and an outer surface of the second portion may be more adjacent to a center of the anode than an outer surface of the first side portion.

In an embodiment, in the forming of the first preliminary partition wall layer, a groove overlapping the opening may be formed in the first preliminary partition wall layer, and the method may further include, before the forming of the second preliminary partition wall layer, providing an organic material in the groove to form an inorganic film.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic perspective view of an electronic apparatus according to an embodiment of the disclosure;

FIG. 2A is a schematic exploded perspective view of the electronic apparatus according to an embodiment of the disclosure;

FIG. 2B is a schematic block diagram of the electronic apparatus according to an embodiment of the disclosure;

FIG. 3 is a schematic cross-sectional view of a display module according to an embodiment of the disclosure;

FIG. 4A is a schematic plan view of a display panel according to an embodiment of the disclosure;

FIG. 4B is a schematic diagram of an equivalent circuit of a pixel according to an embodiment of the disclosure;

FIG. 5 is a schematic enlarged plan view illustrating a portion of a display area of the display panel according to an embodiment of the disclosure;

FIG. 6 is a schematic cross-sectional view of the display panel according to an embodiment of the disclosure;

FIG. 7A is a schematic cross-sectional view of the display panel according to an embodiment of the disclosure;

FIG. 7B is a schematic enlarged view of area AA′ of FIG. 7A;

FIG. 8 is a schematic cross-sectional view of the display panel according to an embodiment of the disclosure;

FIG. 9A is a schematic cross-sectional view of the display panel according to an embodiment of the disclosure;

FIG. 9B is a schematic enlarged view of area BB′ of FIG. 7A;

FIG. 10 is a schematic flowchart illustrating a method for manufacturing a display panel according to an embodiment of the disclosure; and

FIGS. 11A to 11N are schematic cross-sectional views illustrating some of processes in the method for manufacturing the display panel according to an embodiment of the disclosure.

### DETAILED DESCRIPTION OF THE EMBODIMENTS

Hereinafter, embodiments of the disclosure will be described with reference to the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Like reference numerals and/or reference characters refer to like elements throughout. Also, in the figures, the thickness, ratio, and dimensions of components are exaggerated for clarity of illustration. The term “and/or” includes any and all combinations of one or more of the associated listed items.

It will be understood that although the terms such as “first” and “second” are used herein to describe various elements, these elements should not be limited by these terms. These terms are used only to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

The meaning of “include” or “comprise” specifies a property, a fixed number, a step, an operation, an element, a component or a combination thereof, but does not exclude other properties, fixed numbers, steps, operations, elements, components or combinations thereof.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, a display device according to an embodiment of the disclosure will be described with reference to the accompanying drawings.

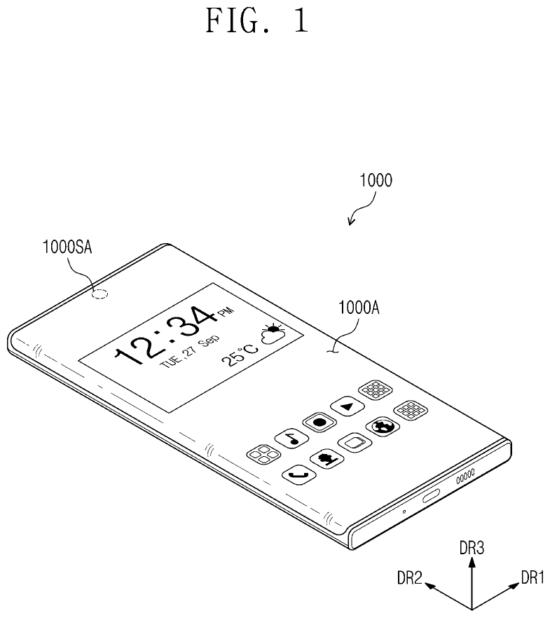

FIG. 1 is a schematic perspective view of an electronic apparatus 1000 according to an embodiment of the disclosure.

Referring to FIG. 1, in this embodiment, a mobile phone may be illustrated as an example of the electronic apparatus 1000. However, the embodiments are not limited thereto, and the electronic apparatus 1000 may be a tablet PC, a monitor, a television, a car navigation system, a game console, or a wearable device.

The electronic apparatus 1000 may display an image through a display area 1000A. The display area 1000A may include a plane defined by a first direction DR1 and a second direction DR2. The display area 1000A may further include curved surfaces that are respectively bent from at least two sides of the plane. However, the shape of the display area 1000A is not limited thereto. For example, the display area 1000A may include only the plane. As another example, the display area 1000A may further include at least two curved surfaces, for example, four curved surfaces that are respectively bent from four sides.

A partial area of the display area 1000A may be defined as a sensing area 1000SA. In FIG. 1, a sensing area 1000SA may be illustrated as an example, but the number of sensing areas 1000SA is not limited thereto. The sensing area 1000SA may be a portion of the display area 1000A and may have a light transmittance greater than that of each of other areas of the display area 1000A except for the sensing area 1000SA. Thus, the sensing area 1000SA may be an area through which light is transmitted while displaying the image. Light (hereinafter, light signal) referred to herein may include, but is not limited to, visible light, and may include various forms as long as the signal is detectable, such as ultraviolet light or infrared light, and is not limited to an embodiment.

The electronic apparatus 1000 may include an electro-optical module disposed on an area overlapping the sensing area 1000SA. The electro-optical module may receive an optical signal provided from the outside through the sensing area 1000SA or output an optical signal through the sensing area 1000SA. For example, the electro-optical module may be a camera module, a sensor that measures a distance between an object such as a proximity sensor and a mobile phone, a sensor that recognizes a portion of the user's body (e.g., fingerprint, iris, or face), or a small lamp that outputs light, but is not particularly limited thereto.

A thickness direction of the electronic apparatus 1000 may be a third direction DR3 which is a normal direction of the display area 1000A. A front surface (or top surface) and a rear surface (or bottom surface) of each of members constituting the electronic apparatus 1000 may be defined based on the third direction DR3.

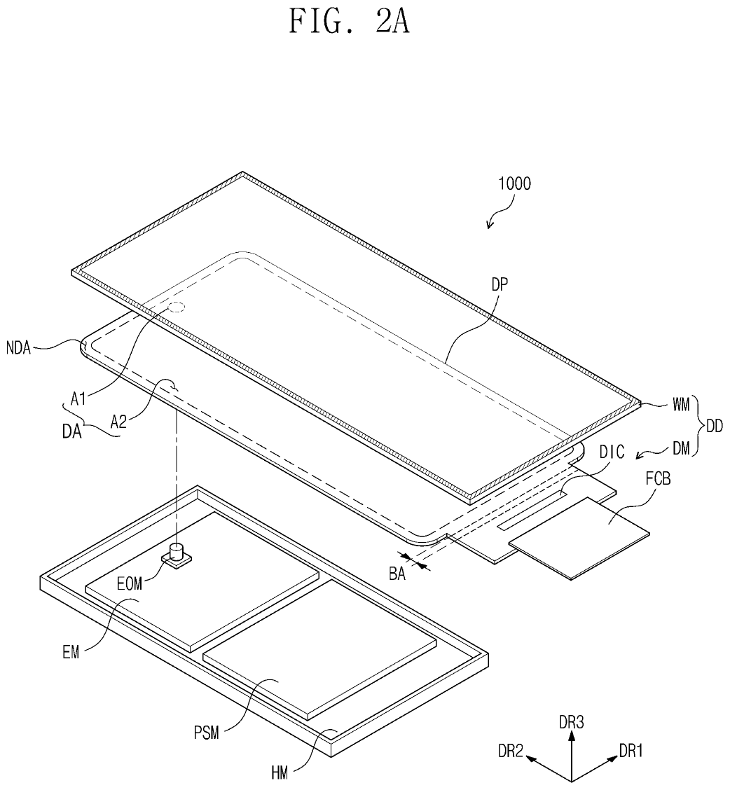

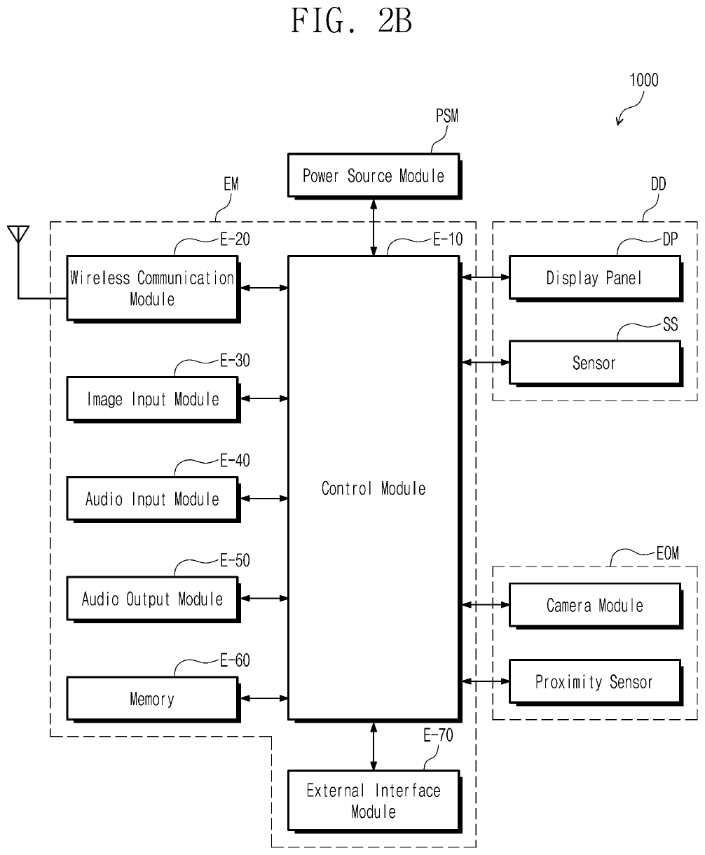

FIG. 2A is a schematic exploded perspective view of the electronic apparatus 1000 according to an embodiment of the disclosure. FIG. 2B is a schematic block diagram of the electronic apparatus 1000 according to an embodiment of the disclosure.

Referring to FIGS. 2A and 2B, the electronic apparatus 1000 may include a display device DD, an electronic module EM, an electro-optical module EOM, a power source module PSM, and a housing HM. The electronic apparatus 1000 may further include additional components (not shown).

The display device DD may generate an image and may sense at least external input. The display device DD may include a window WM and a display module DM.

The window WM may provide a front surface of the electronic apparatus 1000. The window WM may include a glass film or a synthetic resin film as a base film. The window WM may further include an anti-reflection layer or an anti-fingerprint layer. The window WM may further include a bezel pattern overlapping a non-display area NDA of a display panel DP. The window WM and the display module DM may be coupled through an adhesive layer (not shown).

The display module DM may include at least a display panel DP. Although only the display panel DP in the laminated structure of the display module DM is illustrated in FIG. 2A, the display module DM may further include components disposed above the display panel DP. Detailed descriptions of the laminated structure of the display module DM will be described below.

The display panel DP may include a display area DA and a non-display area NDA. The display area DA may correspond to the display area 1000A illustrated in FIG. 1. A pixel PX may be disposed on the display area DA. Specifically, a light-emitting element may be disposed on the display area DA, and the light-emitting element may not be disposed on the non-display area NDA. In this specification, the words “an area or a portion and an area or a portion correspond to each other” may mean that an area or a portion and an area or a portion overlap each other, but the meanings thereof are not limited to the same surface area. The display area DA may include a first area A1 and a second area A2.

The first area A1 may overlap the sensing area 1000SA of the electronic apparatus 1000. Although the first area A1 is illustrated as having a circular shape in FIG. 2A, the embodiment are not limited thereto. Unlike illustrated in FIG. 2A, the first area A1 may have various shapes such as a polygon, an ellipse, a shape having at least one curved side, or an irregular shape. The first area A1 may be referred to as a component area, and the second area A2 may be referred to as a main display area or a general display area.

At least a portion of the first area A1 may have a transmittance greater than that of the second area A2. As another example, the first area A1 may have a resolution less than that of the second area A2, but is not limited thereto. For example, at least a portion of the first area A1 may have a transmittance greater than that of the second area A2, but the resolution of the first area A1 may be substantially the same as that of the second area A2. The first area A1 may overlap the electro-optical module EOM to be described below.

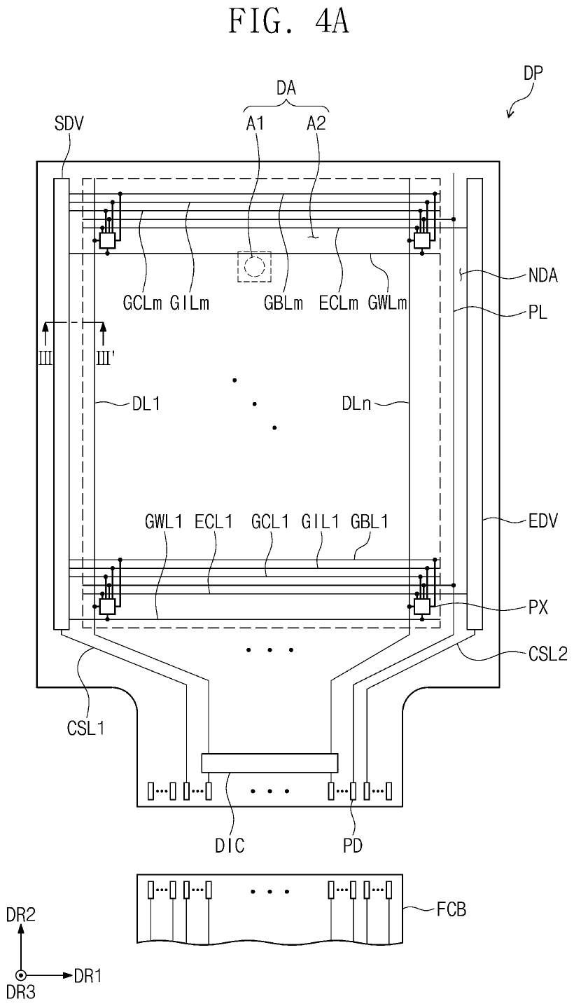

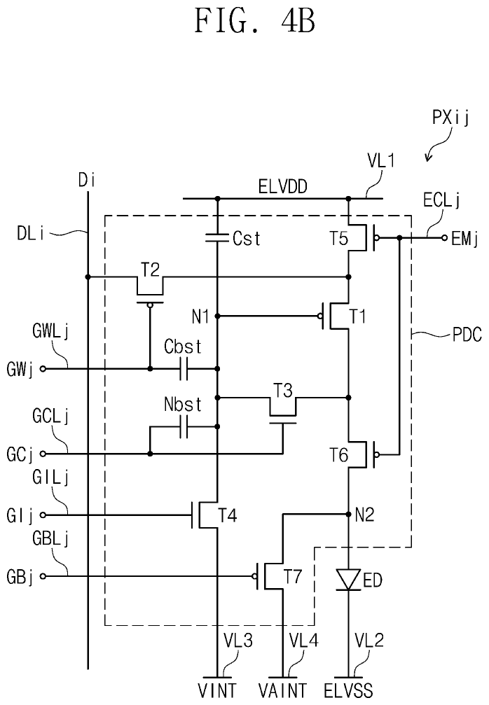

The display panel DP may include pixels PX (see FIG. 4A). The pixels PX (see FIG. 4A) may include a first pixel emitting light on the first area A1 and a second pixel emitting light on the second area A2. Each of the first pixel and the second pixel may be provided in plurality. In this case, each of the first and second pixels may include a red pixel, a green pixel, and a blue pixel and may further include a white pixel according to embodiments. The first pixel may include a first light-emitting element and a first pixel circuit driving the first light-emitting element, and the second pixel may include a second light-emitting element and a second pixel circuit driving the second light-emitting element.

The first area A1 may overlap or correspond to the sensing area 1000SA illustrated in FIG. 1. For example, the first area A1 may be provided on (or in) an area overlapping the electro-optical module EOM illustrated in FIG. 2A on a plane. For example, an external input (e.g., light) may be provided to the electro-optical module EOM through the first area A1, and an output from the electro-optical module EOM may be emitted to the outside through the first area A1.

To secure the area of the transmission area, the smaller number of pixels may be provided on the first area A1 than on the second region A2. The number of first pixels disposed on the first area A1 within a unit area or the same area may be less than the number of second pixels disposed on the second area A2. For example, the resolution of the first area A1 may be about ½, ⅜, ⅓, ¼, 2/9, ⅛, 1/9, 1/16, etc., of the resolution of the second area A2. For example, the resolution of the second area A2 may be about 400 ppi or more, and the resolution of the first area A1 may be about 200 ppi or about 100 ppi. However, this is only an example and the embodiments are not particularly limited thereto.

As illustrated in FIG. 2A, a driving chip DIC may be disposed on the non-display area NDA of the display panel DP. A flexible circuit board FCB may be coupled (or connected) to the non-display area NDA of the display panel DP. The flexible circuit board FCB may be connected to a main circuit board. The main circuit board may be one electronic component constituting the electronic module EM. The bending area BA of the non-display area NDA may be bent so that the flexible circuit board FCB is disposed below the display area DA.

The driving chip DIC may include driving elements for driving the pixels, for example, a data driving circuit. FIG. 2A illustrates a structure in which the driving chip DIC is mounted on the display panel DP, but the embodiment of the disclosure is not limited thereto. For example, the driving chip DIC may be mounted on the flexible circuit board FCB.

The electronic module EM and the power module PSM may be accommodated in the housing HM. The housing HM may be coupled to the display device DD, particularly, the window WM to accommodate other modules.

As illustrated in FIG. 2B, the display device DD may include a display panel DP and a sensor SS. The sensor SS may include at least one of an input sensor, an antenna sensor, and a fingerprint sensor.

The electronic module EM may include a control module E-10, a wireless communication module E-20, an image input module E-30, an audio input module E-40, an audio output module E-50, a memory E-60, and an external interface module E-70. The electronic module EM may include a main circuit board, and the modules may be mounted on the main circuit board or electrically connected to the main circuit board through the flexible circuit board. The electronic module EM may be electrically connected to the power source module PSM.

The control module E-10 may control an overall operation of the electronic apparatus 1000. For example, the control module E-10 may activate or inactivate a display device DD according to the user input. The control module E-10 may control the image input module E-30, the audio input module E-40, the audio output module E-50, and the like to correspond to the user input. The control module E-10 may include at least one microprocessor.

The wireless communication module E-20 may transmit/receive a wireless signal to/from the other terminal by using Bluetooth or Wi-Fi. The wireless communication module E-20 may transmit/receive a voice signal by using a general communication line. The wireless communication module E-20 may include antenna modules.

The image input module E-30 may process an image signal to convert the processed image signal into image data that may be displayed on the display device DD. The audio input module E-40 may receive an external audio signal by using a microphone in a recording mode or a voice recognition mode to convert the received audio signal into electrical sound data. The audio output module E-50 may convert the audio data received from the wireless communication module 20 or the audio data stored in the memory E-60 and may output the converted audio data to the outside.

The external interface module E-70 may serve as an interface connected to an external charger, a wired/wireless data port, and a card socket (for example, a memory card and an SIM/UIM card).

The power source module PSM supplies power necessary for the overall operation of the electronic apparatus 1000. The power source module PSM may include a typical battery device.

The electro-optical module EOM may be an electronic component that outputs or receives an optical signal. The electro-optical module EOM may include a camera module and/or a proximity sensor. The camera module may photograph an external image through the sensing area 1000SA.

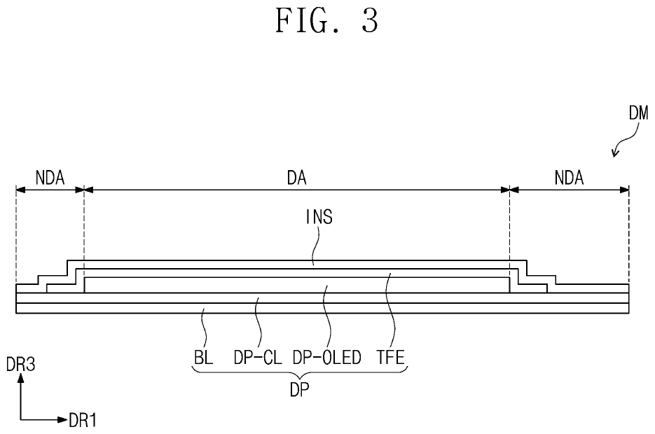

FIG. 3 is a schematic cross-sectional view of a display module according to an embodiment of the disclosure.

Referring to FIG. 3, the display module DM may include a display panel DP and an input sensor INS. Although not separately shown, the display device DD (see FIG. 2A) according to an embodiment of the disclosure may further include an antireflection member and/or a window member disposed on a top surface of a protection member or the input sensor INS disposed on a bottom surface of the display panel DP.

The display panel DP may be an emission type display panel. However, this is merely an example, and the embodiment of the disclosure is not limited thereto. For example, the display panel DP may be an organic light-emitting display panel or an inorganic light-emitting panel. A light-emitting layer within the organic light-emitting display panel may include an organic light-emitting material. A light-emitting layer within the inorganic light-emitting display panel may include quantum dots, quantum rods, or micro LEDs. Hereinafter, the display panel DP may be described as the organic light-emitting display panel.

The display panel DP may include a base layer BL, a circuit element layer DP-CL disposed on the base layer BL, a display element layer DP-OLED, and/or a thin film encapsulation layer TFE. The input sensor INS may be directly disposed on the thin film encapsulation layer TFE. In this specification, that “a constituent A is directly disposed on a constituent B” may mean that an adhesive layer is not disposed between the constituents A and B.

The base layer BL may include at least one plastic film. The base layer BL may include a plastic substrate, a glass substrate, a metal substrate, or an organic/inorganic composite substrate as a flexible substrate. The display area DA and the non-display area NDA described with reference to FIG. 2A may be substantially equally defined on the base layer BL.

The circuit element layer DP-CL may include at least one insulating layer and circuit element. The insulating layer may include at least one inorganic layer and at least one organic layer. The circuit element may include signal lines, a driving circuit of the pixel, and the like.

The display element layer DP-OLED may include a partition wall and a light-emitting element. The light-emitting element may include an anode, an intermediate layer, and a cathode.

The thin film encapsulation layer TFE may include thin films. Some of the thin films may be disposed to improve optical efficiency, and others of the thin films may be disposed to protect the organic light-emitting diodes.

The input sensor INS may acquire coordinate information of an external input. The input sensor INS may have a multilayer structure. The input sensor INS may include a single layer or multi-layered conductive layer. In addition, the input sensor INS may include a single layer or multi-layered insulating layer. The input sensor INS may sense an external input in a capacitive manner. However, this is merely an example, and the embodiment of the disclosure is not limited thereto. For example, in an embodiment, the input sensor INS may sense an external input in an electromagnetic induction manner or a pressure sensing manner. In another embodiment of the disclosure, the input sensor INS may be omitted.

FIG. 4A is a schematic plan view of a display panel according to an embodiment of the disclosure.

Referring to FIG. 4A, a display area DA and a non-display area NDA around the display area DA may be defined on the display panel DP. The display area DA and the non-display area NDA may be distinguished according to whether the pixel PX is disposed. The pixel PX may be disposed on the display area DA. A scan driver SDV, a data driver, and an emission driver EDV may be disposed on the non-display area NDA. The data driver may be a partial circuit configured in a driving chip DIC.

The display panel DP may include pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, and pads PD. Here, m and n are natural numbers greater than or equal to 2.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and be electrically connected to the scan driver SDV. The data lines DL1 to DLn may extend in the second direction DR2 and may be electrically connected to the driving chip DIC. The emission control lines ECL1 to ECLm may extend in the first direction DR1 and be electrically connected to the emission driver EDV.

A driving voltage line PL may include a portion extending, e.g., in the first direction DR1 and a portion extending in the second direction DR2. The portion extending in the first direction DR1 and the portion extending in the second direction DR2 may be disposed on different layers. The driving voltage line PL may provide a driving voltage to the pixels PX.

The first control line CSL1 may be connected to the scan driver SDV. The second control line CSL2 may be connected to the emission driver EDV.

The driving chip DIC, the driving voltage line PL, the first control line CSL1, and the second control line CSL2 may be electrically connected to the pads PD. A circuit board FCB may be electrically connected to the pads PD through an anisotropic conductive adhesive layer. The pads PD may be pads for connecting the circuit board FCB to the display panel DP. The pads PD may be connected to corresponding pixels PX through the driving voltage line PL, the first control line CSL1, and the second control line CSL2.

In addition, the pads PD may further include input pads. The input pads may be pads for connecting the circuit board FCB to the input sensor INS (see FIG. 4). However, the embodiment of the disclosure is not limited thereto, and the input pads may be disposed on the input sensor INS and connected to the pads PD and a separate circuit board. As another example, the input sensor INS may be omitted and may not further include input pads.

FIG. 4B is a schematic diagram of an equivalent circuit of a pixel according to an embodiment of the disclosure.

Specifically, FIG. 4B is a diagram of an equivalent circuit illustrating an example of one pixel PXij of the pixels PX (see FIG. 4A). Since the pixels PX may have the same circuit structure, repetitive descriptions of other pixels PX will be omitted.

Referring to FIGS. 4A and 4B, the pixel PXij may be connected to an i-th data line DLi of the data lines DL1 to DLn, a j-th initialization scan line GILj of the initialization scan lines GIL1 to GILm, a j-th compensation scan line GCLj of the compensation scan lines GCL1 to GCLm, a j-th write scan line GWLj of the write scan lines GWL1 to GWLm, a j-th black scan line GBLj of the black scan lines GBL1 to GBLm, a j-th emission control line ECLj of the emission control lines ECL1 to ECLm, first and second driving voltage lines VL1 and VL2, and first and second initialization voltage lines VL3 and VL4. Here, i is an integer greater than or equal to 1 and less than or equal to n, and j is an integer greater than or equal to 1 and less than or equal to m.

The pixel PXij may include a light-emitting element ED and a pixel circuit PDC. The light-emitting element ED may be a light-emitting diode. As an example of the disclosure, the light-emitting element ED may be an organic light-emitting diode including an organic light-emitting layer, but is not particularly limited thereto. The pixel circuit PDC may control an amount of current flowing in the light-emitting element ED in response to a data signal Di. The light-emitting element ED may emit light having a luminance (e.g., a predetermined or selectable luminance) corresponding to an amount of current supplied from the pixel circuit PDC.

The pixel circuit PDC may include first to seventh transistors T1, T2, T3, T4, T5, T6, and T7, and first to third capacitors Cst, Cost, and Nbst. According to the disclosure, a configuration of the pixel circuit PDC is not limited to the embodiment illustrated in FIG. 4B. The pixel circuit PDC illustrated in FIG. 4B is merely an example, and the configuration of the pixel circuit PDC may be modified to be implemented.

In an embodiment, at least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

Particularly, the first transistor T1, which directly affects brightness of the light-emitting element ED, may be configured to include a highly reliable polycrystalline silicon semiconductor layer, through which a high-resolution display device may be implemented. Since the oxide semiconductor has high carrier mobility and low leakage current, even if a driving time is long, voltage drop may not be large. For example, since a color change of an image due to the voltage drop is not large even during low-frequency driving, low-frequency driving may be possible. As described above, in the case of the oxide semiconductor, since the leakage current is small, at least one of the third transistor T3 and the fourth transistor T4 connected to a gate electrode of the first transistor T1 may be employed as the oxide semiconductor to prevent the leakage current flowing to the gate electrode and also reduce power consumption.

Some of the first to seventh transistors T1, T2, T3, T4, T5, T6, and T7 may be P-type transistors, and others may be N-type transistors. For example, the first, second, fifth, sixth, and seventh transistors T1, T2, T5, T6, and T7 may be P-type transistors, and the third and fourth transistors T3 and T4 may be N-type transistors.

The configuration of the pixel circuit PDC according to the disclosure is not limited to the embodiment illustrated in FIG. 4B. The pixel circuit PDC illustrated in FIG. 4B is merely an example, and the configuration of the pixel circuit PDC may be modified to be implemented. For example, all of the first to seventh transistors T1, T2, T3, T4, T5, T6, and T7 may be P-type transistors or N-type transistors. As another example, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may transmit a j-th initialization scan signal GIj, a j-th compensation scan signal GCj, a j-th write scan signal GWj, a j-th black scan signal GBj, and a j-th emission control signal EMj to the pixel PXij, respectively. The i-th data line DLi may transmit an i-th data signal Di to the pixel PXij. The i-th data signal Di may have a voltage level corresponding to an image signal inputted to the display device DD (see FIG. 2A).

The first and second driving voltage lines VL1 and VL2 may transmit a first driving voltage ELVDD and a second driving voltage ELVSS to the pixel PXij, respectively. The first and second initialization voltage lines VL3 and VLA may transmit first and second initialization voltages VINT and VAINT to the pixel PXij, respectively.

The first transistor T1 may be connected between the first driving voltage line VL1 receiving the first driving voltage ELVDD and the light-emitting element ED. The first transistor T1 may include a first electrode connected to the first driving voltage line VL1 via the fifth transistor T5, a second electrode connected to the pixel electrode (or referred to as an anode) of the light-emitting element ED via the sixth transistor T6, and a third electrode (e.g., gate electrode) connected to an end (e.g., first node N1) of a first capacitor Cst. The first transistor T1 may receive the i-th data signal Di transmitted from the i-th data line DLi according to a switching operation of the second transistor T2 to supply driving current to the light-emitting clement ED.

The second transistor T2 may be connected between the data line DLi and the first electrode of the first transistor T1. The second transistor T2 may include a first electrode connected to the data line DLi, a second electrode connected to the first electrode of the first transistor T1, and a third electrode (e.g., gate electrode) connected to a j-th write scan line GWLj. The second transistor T2 may be turned on according to the write scan signal GWj transmitted through the j-th write scan line GWLj to transmit the i-th data signal Di transmitted from the i-th data line DLi to the first electrode of the first transistor T1. An end of a second capacitor Cbst may be connected to the third electrode of the second transistor T2, and another end of the second capacitor Cbst may be connected to the first node N1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., gate electrode) connected to the j-th compensation scan line GCLj. The third transistor T3 may be turned on according to the j-th compensation scan signal GCj transmitted through the j-th compensation scan line GCLj to connect the third electrode of the first transistor T1 to the second electrode of the first transistor T1, thereby diode-connecting the first transistor T1. An end of a third capacitor Nbst may be connected to the third electrode of the third transistor T3, and another end of the third capacitor Nbst may be connected to the first node N1.

The fourth transistor T4 may be connected between the first initialization voltage line VL3, to which the first initialization voltage VINT is applied, and the first node N1. The fourth transistor T4 may include a first electrode connected to the first initialization voltage line VL3, to which the first initialization voltage VINT is transmitted, a second electrode connected to the first node N1, and a third electrode (e.g., gate electrode) connected to the j-th initialization scan line GILj. The fourth transistor T4 may be turned on according to the j-th initialization scan signal GIj transmitted through the j-th initialization scan line GILj. The fourth transistor T4 turned on may transmit the first initialization voltage VINT to the first node NI to initialize a potential of the third electrode (e.g., potential of the first node N1) of the first transistor T1.

The fifth transistor T5 may include a first electrode connected to the first driving voltage line VL1, a second electrode connected to the first electrode of the first transistor T1, and a third electrode (e.g., gate electrode) connected to the j-th emission control line ECLj. The sixth transistor T6 may include a first electrode connected to the second electrode of the first transistor T1, a second electrode connected to the pixel electrode of the light-emitting element ED, and a third electrode (e.g., gate electrode) connected to the j-th emission control line ECLj.

The fifth and sixth transistors T5 and T6 may be simultaneously turned on according to the j-th emission control signal EMj transmitted through the j-th emission control line ECLj. The first driving voltage ELVDD applied through the fifth transistor T5 turned on may be compensated through the diode-connected first transistor T1 and be transferred to the light-emitting element ED through the sixth transistor T6.

The seventh transistor T7 may include a first electrode connected to the second initialization voltage line VLA, to which the second initialization voltage VAINT is transmitted, a second electrode connected to a second node N2 that is connected to the second electrode of the sixth transistor T6, and a third electrode (e.g., gate electrode) connected to the black scan line GBLj. The second initialization voltage VAINT may have a voltage level equal to or less than that of the first initialization voltage VINT.

An end of the first capacitor Cst may be connected to the third electrode of the first transistor T1, and another end of the first capacitor Cst may be connected to the first driving voltage line VL1. The cathode of the light-emitting element ED may be connected to the second driving voltage line VL2 that transmits the second driving voltage ELVSS. The second driving voltage ELVSS may have a voltage level less than that of the first driving voltage ELVDD.

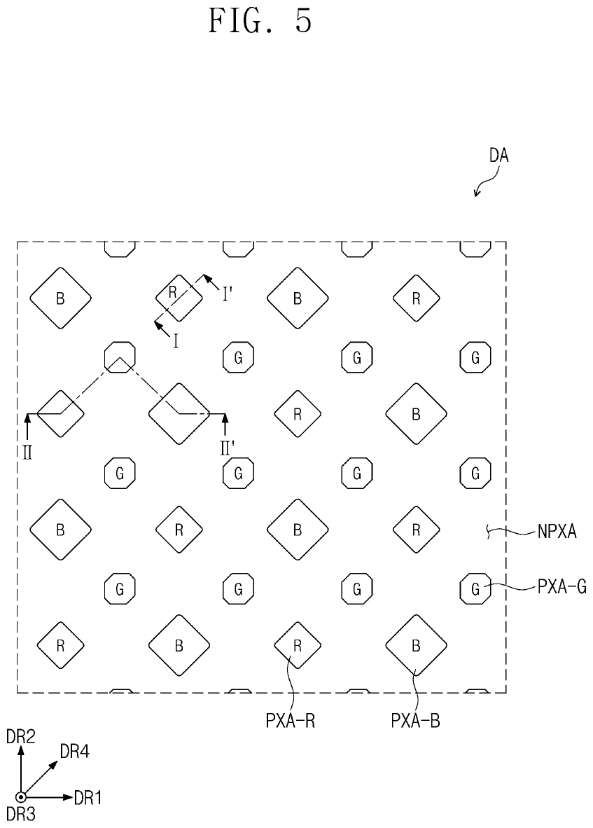

FIG. 5 is a schematic enlarged plan view illustrating a portion of a display area of the display panel according to an embodiment of the disclosure.

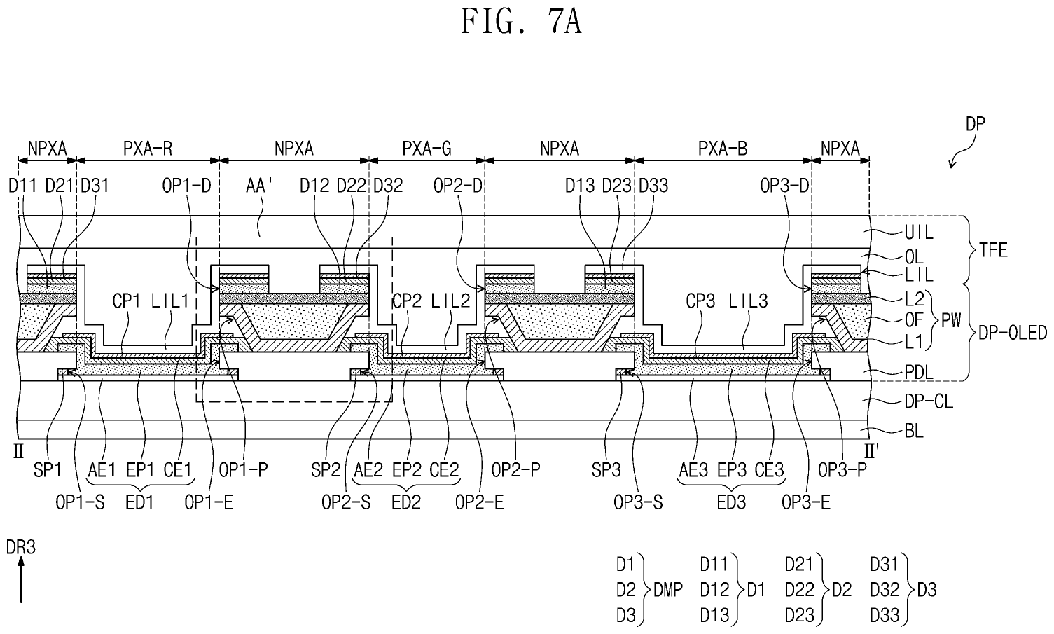

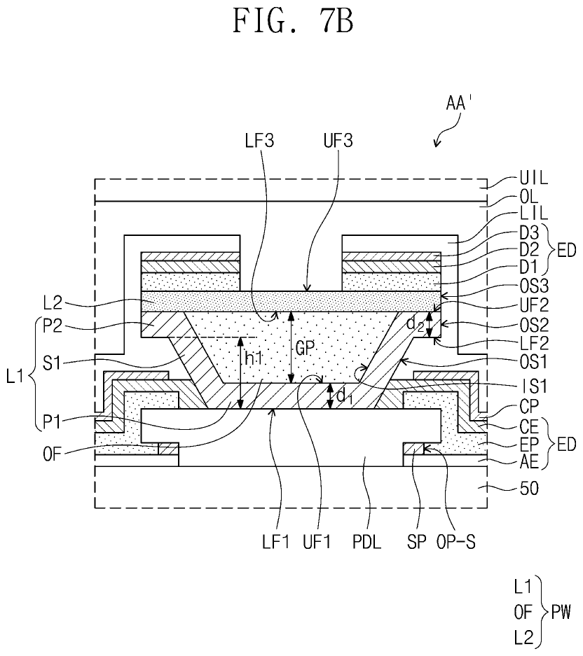

Referring to FIG. 5, the display area DA may include first to third emission areas PXA-R, PXA-G, and PXA-B and a peripheral area NPXA surrounding the first to third emission areas PXA-R, PXA-G, and PXA-B. The first to third emission areas PXA-R, PXA-G, and PXA-B may correspond to areas from which light provided from light-emitting elements ED1, ED2, and ED3 (see FIG. 7A) is emitted, respectively. The first to third emission areas PXA-R, PXA-G, and PXA-B may be classified according to a color of light emitted toward the outside of the display module DM (see FIG. 2).

The first to third emission areas PXA-R, PXA-G, and PXA-B may provide first to third color light having different colors, respectively. For example, the first color light may be red light, the second color light may be green light, and the third color light may be blue light. However, examples of the first to third color light are not necessarily limited to the above example.

Each of the first to third emission areas PXA-R, PXA-G, and PXA-B may be defined as an area in which a top surface of the anode is exposed by a light-emitting opening to be described below. The peripheral area NPXA may set a boundary between the first to third emission areas PXA-R, PXA-G, and PXA-B to prevent colors from being mixed with each other between the first to third emission areas PXA-R, PXA-G, and PXA-B.

Each of the first to third emission areas PXA-R, PXA-G, and PXA-B may be provided in plurality and repeatedly disposed in an arrangement form (e.g., a predetermined or selectable arrangement form) within the display area DA. For example, the first and third emission areas PXA-R and PXA-B may be alternately arranged in the first direction DR1 to constitute a ‘first group’. The second emission areas PXA-G may be arranged in the first direction DR1 to constitute a ‘second group’. Each of the ‘first group’ and the ‘second group’ may be provided in plurality, and the ‘first groups’ and the ‘second groups’ may be alternately arranged in the second direction DR2.

A second emission area PXA-G may be disposed to be spaced apart from a first emission area PXA-R or a third emission area PXA-B in the fourth direction DR4. The fourth direction DR4 may be a direction between the first direction DR1 and the second direction DR2.

FIG. 5 illustrates an arrangement of the first to third emission areas PXA-R, PXA-G, and PXA-B as an example, but the embodiments are not limited thereto and may be arranged in various forms. In an embodiment, the first to third emission areas PXA-R, PXA-G, and PXA-B may have a PENTILE™ arrangement as illustrated in FIG. 5. As another example, the first to third emission areas PXA-R, PXA-G, and PXA-B may have a stripe arrangement or a Diamond Pixel™ arrangement.

The first to third emission areas PXA-B, PXA-G, and PXA-R may have various shapes on the plane. For example, each of the first to third emission areas PXA-R, PXA-G, and PXA-B may have a polygonal, circular, or elliptical shape. FIG. 5 illustrates first and third emission areas PXA-R and PXA-B, each of which has a quadrangular shape (or diamond shape), and a second emission area PXA-G having an octagonal shape on the plane as an example.

The first to third emission areas PXA-R, PXA-G, and PXA-B may have the same shape on the plane, or at least some of the first to third emission areas PXA-R, PXA-G, and PXA-B may have a different shape. FIG. 5 illustrates first and third emission areas PXA-R and PXA-B having the same shape on the plane and the second emission area PXA-G having a shape different from that of each of the first and third emission areas PXA-R and PXA-B as an example.

At least some of the first to third emission areas PXA-R, PXA-G, and PXA-B may have a different area on the plane. In an embodiment, a surface area of the first emission area PXA-R emitting the red light may be greater than that of the second emission area PXA-G emitting the green light, and may be less than that of the third emission area PXA-B emitting the blue light. However, a size relationship in area between the first to third emission areas PXA-R, PXA-G, and PXA-B according to the emission color is not limited thereto and may vary according to a design of the display module DM (see FIG. 2). The embodiments of the disclosure are not limited thereto, and the first to third emission areas PXA-R, PXA-G, and PXA-B may have the same area on the plane.

In the display module DM (see FIG. 2) of the disclosure, the shape, the surface area, the arrangement, etc., of the first to third emission areas PXA-R, PXA-G, and PXA-B may be variously designed according to the colors of the emitted light or the size and configuration of the display module DM (see FIG. 2), but are not limited to the embodiment illustrated in FIG. 5.

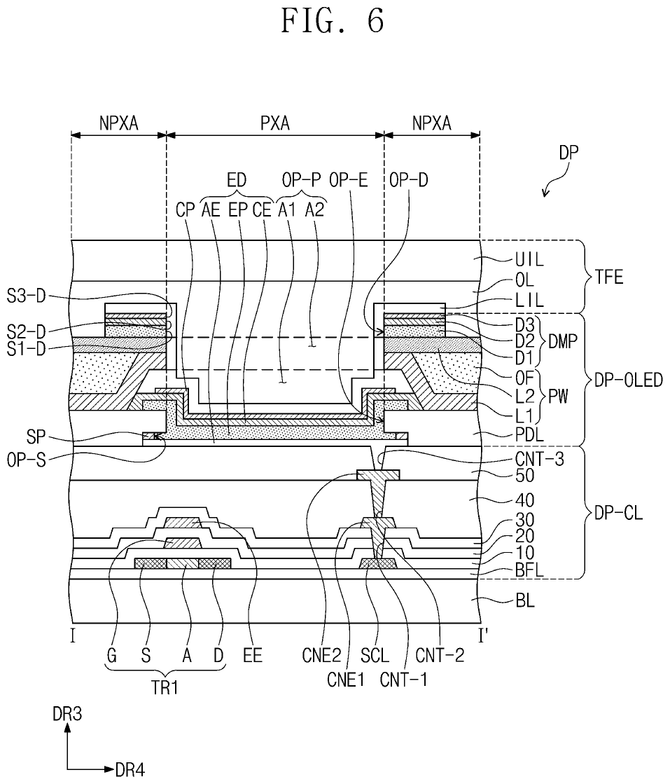

FIG. 6 is a schematic cross-sectional view of the display panel according to an embodiment of the disclosure. FIG. 6 is a schematic cross-sectional view taken along line I-I′ of FIG. 5. FIG. 7A is a schematic cross-sectional view of the display panel according to an embodiment of the disclosure. FIG. 7A is a schematic cross-sectional view taken along line II-II′ of FIG. 5. FIG. 7B is a schematic enlarged view of area AA′ of FIG. 7A. In the description of FIGS. 6, 7A, ad 7B, it will be described with reference to FIG. 5, and descriptions of the configurations having the same reference numerals will be omitted.

FIG. 6 is a schematic enlarged view of one emission area PXA within the display area DA (see FIG. 5), and the emission area PXA of FIG. 6 may correspond to one of the first to third emission areas PXA-R, PXA-G, and PXA-B of FIG. 5.

Referring to FIG. 6, the display panel DP may include a base layer BL, a circuit clement layer DP-CL, a display element layer DP-OLED, and a thin film encapsulation layer TFE.

The display panel DP may include insulating layers, a semiconductor pattern, a conductive pattern, a signal line, and the like. The insulating layer, the semiconductor layer, and the conductive layer may be formed in a manner such as coating, deposition, or the like. Thereafter, the insulating layer, the semiconductor layer, and the conductive layer may be selectively patterned through photolithography and etching processes. The semiconductor pattern, the conductive pattern, and the signal line, which are provided in the circuit element layer DP-CL and the display element layer DP-OLED, may be formed in the above-described manner.

The circuit element layer DP-CL may be disposed on the base layer BL. The circuit element layer DP-CL may include a buffer layer BFL, a transistor TR1, a signal transmission area SCL, first to fifth insulating layers 10, 20, 30, 40, and 50, an upper electrode EE, and connection electrodes CNE1 and CNE2.

The buffer layer BFL may be disposed on the base layer BL. The buffer layer BFL may improve bonding force between the base layer BL and the semiconductor pattern. The buffer layer BFL may include a silicon oxide layer and a silicon nitride layer. The silicon oxide layer and the silicon nitride layer may be alternately laminated.

A semiconductor pattern may be disposed on the buffer layer BFL. The semiconductor pattern may include various materials, e.g., polysilicon. However, the embodiments of the disclosure is not limited thereto. For example, the semiconductor pattern may include amorphous silicon or metal oxide. In FIG. 6, a portion of the semiconductor pattern is illustrated as an example, and semiconductor patterns may be further disposed on the emission areas PXA-R, PXA-G, and PXA-B (see FIG. 5). The semiconductor pattern may be arranged in a specific rule over the emission areas PXA-R, PXA-G, and PXA-B. The semiconductor pattern may have different electrical properties depending on whether the semiconductor pattern is doped. The semiconductor pattern may include a first region having a high doping concentration and a second region having a low doping concentration. The first region may be doped with an N-type dopant or a P-type dopant. A P-type transistor may include the first region doped with the P-type dopant.

The first area may have conductivity greater than that of the second area and may substantially serve as an electrode or a signal line. The second region may substantially correspond to an active (or channel) of the transistor. For example, a portion of the semiconductor pattern may be an active of the transistor, another portion thereof may be a source or a drain of the transistor, and further another portion thereof may be a conductive area.

A source S, an active A, and a drain D of the transistor TR1 may be formed from the semiconductor pattern. FIG. 6 illustrates a portion of a signal transmission area SCL formed from the semiconductor pattern. Although not particularly shown, the signal transmission area SCL may be connected to the drain D of the transistor TR1 on the plane.

The first to fifth insulating layers 10, 20, 30, 40, and 50 may be disposed on the buffer layer BFL. Each of the first to fifth insulating layers 10, 20, 30, 40, and 50 may be an organic layer or an inorganic layer.

A first insulating layer 10 may be disposed on the buffer layer BFL. The first insulating layer 10 may cover the source S, the active A, the drain D of the transistor TR1 and the signal transmission area SCL disposed on the buffer layer BFL. A gate G of the transistor TR1 may be disposed on the first insulating layer 10. The second insulating layer 20 may be disposed on the first insulating layer 10 to cover the gate G. An upper electrode EE may be disposed on the second insulating layer 20. The third insulation layer 30 may be disposed on the second insulation layer 20 to cover the upper electrode EE.

A first connection electrode CNE1 may be disposed on the third insulating layer 30. The first connection electrode CNE1 may be connected to the signal transmission area SCL through a contact hole CNT-1 passing through the first to third insulating layers 10 to 30. A fourth insulating layer 40 may be disposed on the third insulating layer 30 to cover the first connection electrode CNE1. The fourth insulating layer 40 may be an organic layer.

A second connection electrode CNE2 may be disposed on the fourth insulating layer 40. The second connection electrode CNE2 may be connected to the first connection electrode CNE1 through a contact hole CNT-2 passing through the fourth insulating layer 40. A fifth insulating layer 50 may be disposed on the fourth insulating layer 40 to cover the second connection electrode CNE2. The fifth insulating layer 50 may be an organic layer.

The display element layer DP-OLED may be disposed on the circuit element layer DP-CL. The display element layer DP-OLED may include a light-emitting element ED, a sacrificial pattern SP, a pixel defining layer PDL, a partition wall PW, and dummy patterns DMP.

The light-emitting element ED may include an anode AE (or first electrode), an emission pattern EP, and a cathode CE (or second electrode). Each of the first to third light-emitting elements ED1, ED2, and ED3 to be described below may have substantially the same configuration as the light-emitting element ED of FIG. 6. The descriptions of the anode AE, the emission pattern EP, and the cathode CE may be substantially equally applied to all of the anode, the emission pattern, and the cathode of each of the first to third light-emitting elements to be described below.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 defined to pass through the fifth insulating layer 50. Thus, the anode AE may be electrically connected to the signal transmission area SCL through the first and second connection electrodes CNE1 and CNE2 and electrically connected to corresponding circuit element. The anode AE may have a single-layer or multi-layered structure. The anode AE may include layers including ITO and Ag. For example, the anode AE may include a layer including ITO (hereinafter, referred to as lower ITO layer), a layer including Ag disposed on the lower ITO layer (hereinafter, referred to as Ag layer), and a layer including ITO disposed on the Ag layer (hereinafter, an upper ITO layer).

The sacrificial pattern SP may be disposed between the anode AE and the pixel defining layer PDL. The sacrificial pattern SP may correspond to a portion of a layer provided to prevent the anode AE from being damaged in a process of forming a partition wall opening OP-P, which will be described below. A sacrificial opening OP-S exposing a portion of a top surface of the anode AE may be defined in the sacrificial pattern SP. The sacrificial opening OP-S may overlap a light-emitting opening OP-E to be described below. The sacrificial pattern SP may include an amorphous transparent conductive oxide. For example, the sacrificial pattern SP may be zinc oxide (ZnOx) doped with aluminum (Al).

The pixel defining layer PDL may be disposed on the fifth insulating layer 50 of the circuit element layer DP-CL. The light-emitting opening OP-E may be defined in the pixel defining layer PDL. The light-emitting opening OP-E may correspond to the anode AE, and the pixel defining layer PDL may expose at least a portion of the anode AE through the light-emitting opening OP-E.

The light-emitting opening OP-E may correspond to the sacrificial opening OP-S of the sacrificial pattern SP. According to this embodiment, the top surface of the anode AE may be spaced apart from the pixel defining layer PDL in a cross-section with the sacrificial pattern SP therebetween, and thus, in the process of forming the light-emitting opening OP-E, the anode AE may be prevented from being damaged.

On a plane, a surface area of the light-emitting opening OP-E may be less than that of the sacrificial opening OP-S. For example, an inner surface of the pixel defining layer PDL defining the light-emitting opening OP-E may be closer to a center of the anode AE than an inner surface of the sacrificial pattern SP defining the sacrificial opening OP-S. However, the embodiment of the disclosure is not limited thereto, and the inner surface of the sacrificial pattern SP defining the sacrificial opening OP-S may be substantially aligned with the inner surface of the pixel defining layer PDL defining the corresponding light-emitting opening OP-E. Here, the emission area PXA may be regarded as an area of the anode AE exposed through the corresponding sacrificial opening OP-S.

The pixel defining layer PDL may include an inorganic insulating material. The pixel defining layer PDL may include, e.g., at least one of silicon oxide (SiOₓ), silicon nitride (SiNₓ), and silicon oxynitride (SiOₓN_{y}). For example, the pixel defining layer PDL may include silicon nitride (SiNₓ). The pixel defining layer PDL may be disposed between the anode AE and the partition wall PW to block electrical connection between the anode AE and the partition wall PW.

The partition wall PW may be disposed on the pixel defining layer PDL. A partition wall opening OP-P may be defined in the partition wall PW. The partition wall opening OP-P may correspond to the light-emitting opening OP-E and may expose at least a portion of the anode AE. The partition wall opening OP-P defined in the partition wall PW may include a first area A1 and a second area A2. A width of the first area A1 in the fourth direction DR4 may be different from a width of the second area A2 in the fourth direction DR4. The width of the first area A1 in the fourth direction DR4 may be greater than that of the second area A2 in the fourth direction DR4. The second area A2 of the partition wall opening OP-P may be an area defining a tip part.

The partition wall PW may have an undercut shape in a cross-section. The partition wall PW may include a first partition wall layer L1, an organic film OF, and/or a second partition wall layer L2. In an embodiment, the partition wall PW may include a first partition wall layer L1, an organic film OF, and a second partition wall layer L2, which are sequentially stacked each other in the third direction DR3 that is a thickness direction.

The first partition wall layer L1 may be disposed adjacent to the pixel defining layer PDL. The first partition wall layer L1 may be disposed on the pixel defining layer PDL. The first partition wall layer L1 may be directly disposed on the pixel defining layer PDL. The first partition wall layer L1 may contact the cathode CE. The cathode CE may contact the first partition wall layer L1 to receive the second driving voltage ELVSS (see FIG. 4B) from the first partition wall layer L1.

Referring to FIGS. 6 and 7B, the first partition wall layer L1 may have a groove shape that is recessed by a height difference (e.g., a predetermined or selectable height difference) in the third direction DR3. The first partition wall layer L1 may have a shape in which a central portion of the first partition wall layer L1 is recessed toward the pixel defining layer PDL on a reference plane that is spaced a height difference (e.g., a predetermined or selectable height difference) from the pixel defining layer PDL. The first partition wall layer L1 may include a first portion P1 disposed on the pixel defining layer PDL, a second portion P2 spaced apart from the pixel defining layer PDL and having a height difference with the first portion P1, and a first side portion S1 connecting the first portion P1 to the second portion P2.

The first portion P1 may be disposed on the pixel defining layer PDL. The first portion P1 may be directly disposed on the pixel defining layer PDL. The first portion P1 may extend along a direction DR4 parallel to a top surface of the base layer BL. The first portion P1 may include a first bottom surface LF1 adjacent to the pixel defining layer PDL and a first top surface UF1 facing the first bottom surface LF1 and spaced apart from the pixel defining layer PDL. The first bottom surface LF1 may contact the pixel defining layer PDL. The first bottom surface LF1 may define the lowermost surface of the partition wall PW.

The first side portion S1 may extend from each of ends of the first portion P1. The first portion S1 may connect the first portion P1 to the second portion P2. The first side portion S1 may be a portion of the first partition wall layer L1, which contacts the cathode CE.

The first side portion S1 of the first partition wall layer L1 may include a first outer surface OS1 adjacent to the anode AE and a first inner surface IS1 facing the first outer surface OS1 and spaced apart from the anode AE. The first outer surface OS1 of the first side portion S1 may extend from the first bottom surface LF1 of the first portion P1 to connect the first bottom surface LF1 to a second bottom surface LF2 of the second portion P2. The first inner surface IS1 of the first side portion S1 may extend from the first top surface UF1 of the first portion P1 to connect the first top surface UF1 to a second top surface UF2 of the second portion P2.

The first side portion S1 may be provided to have an inclination. Each of the first inner surface IS1 and the first outer surface OS1 of the first side portion S1 may be an inclined surface. In an embodiment, an inclination of each of the first inner surface IS1 and the first outer surface OS1 may be an obtuse angle. Here, the inclination of the first inner surface IS1 and the first outer surface OS1 may refer to an angle between each of the first inner surface IS1 and the first outer surface OS1 and the top surface of the base layer BL. For example, each of the angle between the first inner surface IS1 and the top surface of the base layer BL and the angle between the first outer surface OS1 and the top surface of the base layer BL may be an obtuse angle. However, the embodiments are not limited thereto, and the inclination of each of the first inner surface IS1 and the first outer surface OS1 may be a right angle or an acute angle.

The second portion P2 may have a height difference with respect to the first portion P1 in the third direction DR3 and may be spaced apart from the first portion P1. The first side portion S1 may include an end connected to the first portion P1 and another end connected to the second portion P2, and the second portion P2 may extend from the another end of the first side portion S1. The second portion P2 may extend in a direction parallel to the fourth direction DR4.

Based on the third direction DR3, the first portion P1 and the second portion P2 may have a first height difference h1. The first height difference hl may be defined as a height difference between the first bottom surface LF1 of the first portion P1 and the second bottom surface LF2 of the second portion P2.

The second portion P2 of the first partition wall layer L1 may include a second bottom surface LF2 extending from the first outer surface OS1 of the first side portion S1, a second top surface UF2 extending from the first inner surface IS1 of the first side portion S1, and a second outer surface OS2 connecting the second bottom surface LF2 to the second top surface UF2. The second bottom surface LF2 of the second portion P2 and the second top surface UF2 of the second portion P2 may face each other in the third direction DR3.

A first thickness di of the first portion P1 and a second thickness d2 of the second portion P2 may be substantially the same. However, the embodiments are not limited thereto, and the first thickness di of the first portion P1 and the second thickness d2 of the second portion P2 may be different from each other. In an embodiment, the thickness of each of the first portion P1 and the second portion P2 may be about 1,000 Å to about 2,000 Å. The thickness of the first portion P1 may be defined as a height difference between the first bottom surface LF1 and the first top surface UF1 of the first portion P1. The thickness of the second portion P2 may be defined as a height difference between the second bottom surface LF2 and the second top surface UF2 of the second portion P2.

The second partition wall layer L2 may be disposed on the first partition wall layer L1. The second partition wall layer L2 may be provided on the first partition wall layer L1 to increase in mechanical strength of the partition wall PW, thereby improving stiffness of an undercut shape of the partition wall PW. The second partition wall layer L2 may provide a tip part disposed on the partition wall PW together with the second portion P2 of the first partition wall layer L1.

The second partition wall layer L2 may extend in a direction parallel to the fourth direction DR4. The second partition wall layer L2 may include a third bottom surface LF3 adjacent to the first partition wall layer L1, a third top surface UF3 facing the third bottom surface LF3 and spaced apart from the first partition wall layer L1, and a third outer surface OS3 connecting the third bottom surface LF3 to the third top surface UF3. The third top surface UF3 of the second partition wall layer L2 may define the uppermost surface of the partition wall PW and may define the top surface of the tip part disposed on the partition wall PW.

The third outer surface OS3 of the second partition wall layer L2 may be aligned with the second outer surface OS2 of the second portion P2 of the first partition wall layer L1 in the third direction DR3. The second outer surface OS2 of the second portion P2 and the third outer surface OS3 of the second partition wall layer L2 may define an alignment surface.

In an embodiment, a spaced space or gap GP may be defined in the partition wall PW. The spaced space GP may be defined by the first portion P1 of the first partition wall layer L1, the first side portion S1 of the first partition wall layer L1, and a portion of the second partition wall layer L2. Specifically, the spaced space GP may be defined by the first top surface UF1 of the first portion P1, the first inner surface IS1 extending from each of ends of the first top surface UF1, and a portion of the third bottom surface LF3 of the second partition wall layer L2.

The organic film OF may be disposed between the first partition wall layer L1 and the second partition wall layer L2. The organic film OF may be disposed within the spaced space GP defined in the partition wall PW. The organic film OF may be filled into at least a portion of the spaced space GP. The organic film OF may be disposed in the spaced space GP to improve the mechanical strength and transparency of the partition wall PW. As the first partition wall layer L1 has a groove shape that is recessed by a height difference (e.g., a predetermined or selectable height difference), it may be broken by an external pressure due to its low mechanical strength, but as the organic film OF is disposed in the spaced space GP defined in the first partition wall layer L1, the mechanical strength of the partition wall PW may be improved. In an embodiment, the organic film OF may be entirely filled into the spaced space GP. The organic film OF may contact each of the first top surface UF1 of the first portion P1 and the first inner surface IS1 of the first side portion S1.

The second partition wall layer L2 may be disposed on the first partition wall layer L1 and the organic film OF. The second partition wall layer L2 may contact the second portion P2 of the first partition wall layer L1 and the organic film OF.

In an embodiment, the first outer surface OS1 of the first side portion S1 may define a first area A1 of the partition wall opening OP-P, the second outer surface OS2 of the second portion P2 may define a portion of a second area A2 of the partition wall opening OP-P, and the third outer surface OS3 of the second partition wall layer L2 may define a remaining portion of the second area A2 of the partition wall opening OP-P.

In an embodiment, the first outer surface OS1 of the first side portion S1 may be relatively recessed when compared to the second outer surface OS2 of the second portion P2 based on the emission area PXA. The second outer surface OS2 of the second portion P2 defining a portion of the second area A2 may be adjacent to a center of the anode AE when compared to the first outer surface OS1 defining the first area A1. The second portion P2 protruding toward the emission area PXA may define the tip part together with the second partition wall layer L2. The second outer surface OS2 may be disposed to be adjacent to the center of the anode AE in a direction, for example, in the fourth direction DR4 when compared to the first outer surface OS1.

The first partition wall layer L1 may include a light-transmitting material. The first partition wall layer L1 may include a transparent conductive material to transmit a signal. For example, the first partition wall layer L1 may include transparent conductive oxide (TCO). The first partition wall layer L1 may include transparent conductive oxide (TCO) such as indium tin oxide (ITO), indium zinc oxide (IZO), indium gallium zinc oxide (IGZO), indium zinc tin oxide (IZTO), zinc oxide (ZnO), or indium oxide (In₂O₃).

In an embodiment, the first partition wall layer L1 may include at least one of indium tin oxide, indium zinc oxide, indium gallium zinc oxide, indium zinc tin oxide, zinc oxide, and indium oxide. The first partition wall layer L1 may be made of at least one of indium tin oxide, indium zinc oxide, indium gallium zinc oxide, indium zinc tin oxide, zinc oxide, and indium oxide. In an embodiment, the first partition wall layer L1 may include indium tin oxide. The first partition wall layer L1 may be made of indium tin oxide.

As the first partition wall layer L1 includes the transparent conductive oxide, a light transmittance of the partition wall PW may be improved. The electronic apparatus 1000 (see FIG. 1) having the sensing area 1000SA (see FIG. 1) may require a high light transmittance on the sensing area 1000SA (see FIG. 1). In case that the partition wall PW is made of a material including an opaque metal, it may be difficult to secure a transmittance because light is blocked by the metal. According to the disclosure, as the first partition wall layer L1 includes the transparent conductive oxide and has the groove shape that is recessed by a height difference (e.g., a predetermined or selectable height difference), since the first partition wall layer L1 has a film structure having a high transmittance and a relatively thin thickness, an amount of light transmitted through the partition wall PW may increase to improve the light transmittance. For example, as the first partition wall layer L1 includes the transparent conductive oxide, transmittance of a light signal may be further improved on the first area A1 corresponding to an area through which the light signal is transmitted on the display panel DP. As the partition wall PW includes the first partition wall layer L1 including the transparent conductive oxide, optical characteristics such as a transmittance of an image displayed by the display device DD may be improved.

The second partition wall layer L2 may include a material having electrical conductivity less than that of the first partition wall layer L1, and having strength greater than that of the first partition wall layer L1. The second partition wall layer L2 may include a material having a high Young's modulus of about 300 GPa or more. Since the second partition wall layer L2 includes the material having the high Young's modulus, a degree of deformation of the second partition wall layer L2 may be reduced. As the degree of deformation of the second partition wall layer L2 constituting the uppermost surface of the tip part decreases, a stiffness of the undercut shape of the partition wall PW may increase. Thus, the shape in which the tip part of the partition wall PW droops may be reduced or removed, and the shape in which the tip part blocks the outer surface of the partition wall PW that contacts the cathode CE may be reduced or removed.

In an embodiment, the second partition wall layer L2 may include a metal material. The second partition wall layer L2 may include gold (Au), silver (Ag), aluminum (Al), magnesium (Mg), lithium (Li), molybdenum (Mo), titanium (Ti), copper (Cu), or an alloy thereof. The second partition wall layer L2 may include a material different from that of the first partition wall layer L1. The second partition wall layer L2 may include, for example, titanium (Ti). A thickness of the second partition wall layer L2 may be about 1,000 Å or more and about 2,000 Å or less.

In the partition wall PW according to an embodiment, the second partition wall layer L2 may not include the metal material. The second partition wall layer L2 may include a silicon-based compound. The second partition wall layer L2 may include at least one of silicon oxide (SiOₓ), silicon nitride (SiNₓ), and silicon oxynitride (SiOₓN_{y}). The second partition wall layer L2 may include, for example, silicon oxide (SiOₓ). Unlike the first partition wall layer L1, the second partition wall layer L2 may not contact the cathode CE and may provide the tip part to separate the cathode CE from each of the emission areas PXA and may include a silicon-based compound which is an insulating material.

The organic film OF may include at least one of an acrylic-based resin, a methacrylic-based resin, a polyisoprene-based resin, a vinyl-based resin, an epoxy-based resin, a urethane-based resin, a cellulose-based resin, a, siloxane-based resin, a polyimide-based resin, a polyamide-based resin, and a perylene-based resin. For example, the organic film OF may include polyimide (Pl) or polyethylene terephthalate (PET).

The emission pattern EP may be disposed on the anode AE. The emission pattern EP may include a light-emitting layer including a light-emitting material. The emission pattern EP may further include a hole injection layer (HIL) and a hole transport layer (HTL), which are disposed between the anode AE and the light-emitting layer, and may further include an electron transport layer (ETL) and an electron injection layer (EIL), which are disposed on the light-emitting layer. The emission pattern EP may also be referred to as an ‘organic layer’ or an ‘intermediate layer’.

The emission pattern EP may be patterned by the tip part defined on the partition wall PW. The emission pattern EP may be disposed inside the sacrificial opening OP-S, the light-emitting opening OP-E, and the partition wall opening OP-P. The emission pattern EP may cover a portion of the top surface of the pixel defining layer PDL exposed through the partition wall opening OP-P.

The cathode CE may be disposed on the emission pattern EP. The cathode CE may be patterned by the tip part defined on the partition wall PW. The cathode CE may contact the first outer surface OS1 of the first partition wall layer L1.

The partition wall PW may receive the second driving voltage ELVSS (see FIG. 4B), and thus, the cathode CE may be electrically connected to the partition wall PW to receive the second driving voltage ELVSS (see FIG. 4B).

According to an embodiment of the disclosure, the display panel DP may further include a capping pattern CP. The capping pattern CP may be disposed in the partition wall opening OP-P and may be disposed on the cathode CE. The capping pattern CP may be patterned by the tip part disposed on the partition wall PW.

Although FIG. 6 illustrates the structure in which the capping pattern CP does not contact the third outer surface OS3 of the second partition wall layer L2, the embodiment of the disclosure is not limited thereto. For example, the capping pattern CP may be configured to contact the third outer surface OS3 of the second partition wall layer L2. According to another embodiment of the disclosure, the capping pattern CP may be omitted.

Dummy patterns DMP may be disposed on the partition wall PW. The dummy patterns DMP may include a first dummy pattern D1, a second dummy pattern D2, and a third dummy pattern D3. The first to third dummy patterns D1, D2, and D3 may be sequentially laminated in the third direction DR3 on the top surface of the second partition wall layer L2 of the partition wall PW.

The first dummy pattern D1 may include an organic material. For example, the first dummy pattern D1 and the emission pattern EP may include a same material. The first dummy pattern D1 may be simultaneously formed together with the emission pattern EP through a process or may be formed separately from the emission pattern EP by the undercut shape of the partition wall PW.

The second dummy pattern D2 may include a conductive material. For example, the second dummy pattern D2 and the cathode CE may include a same material. The second dummy pattern D2 may be simultaneously formed together with the cathode CE through one process or may be formed separately from the cathode CE by the undercut shape of the partition wall PW.

The third dummy pattern D3 and the capping pattern CP may include a same material. The third dummy pattern D3 may be simultaneously formed together with the capping pattern CP through one process or may be formed separately from the capping pattern CP by the undercut shape of the partition wall PW.

Dummy openings OP-D may be defined in the dummy patterns DMP. The dummy opening OP-D may correspond to the light-emitting opening OP-E. The dummy opening OP-D may include first to third areas that are sequentially arranged in the third direction DR3. The first area of the dummy opening OP-D may be defined by an inner surface S1-D of the first dummy pattern D1, the second area may be defined by an inner surface S2-D of the second dummy pattern D2, and the third area may be defined by an inner surface S3-D of the third dummy pattern D3. On a plane, each of the first to third dummy patterns D1, D2, and D3 may have a closed-line shape surrounding the emission area PXA.

Although FIG. 6 illustrates the structure in which the inner surfaces of the first to third dummy patterns D1, D2, and D3 and the third outer surface OS3 of the second partition wall layer L2 are aligned with each other, the embodiments of the disclosure is not limited thereto. For example, the first to third dummy patterns D1, D2, and D3 may cover the third outer surface OS3 of the second partition wall layer L2.

The thin film encapsulation layer TFE may be disposed on the display element layer DP-OLED. The thin film encapsulation layer TFE may include a lower encapsulation inorganic pattern LIL, an encapsulation organic layer OL, and/or an upper encapsulation inorganic layer UIL.

The lower encapsulation inorganic pattern LIL may correspond to the light-emitting opening OP-E. The lower encapsulation inorganic pattern LIL may cover the light-emitting element ED and the dummy patterns DMP, and a portion of the lower encapsulation inorganic pattern LIL may be disposed inside the partition wall opening OP-P. According to an embodiment, the lower encapsulation inorganic pattern LIL may contact each of the first outer surface OS1 and the second outer surface OS2 of the first partition wall layer L1 and the third outer surface OS3 of the second partition wall layer L2.

The encapsulation organic layer OL may cover the lower encapsulation inorganic pattern LIL and provide a flat top surface. The upper encapsulation inorganic layer UIL may be disposed on the encapsulation organic layer OL.

The lower encapsulation inorganic pattern LIL and the upper encapsulation inorganic layer UIL may protect the display element layer DP-OLED from moisture/oxygen, and the encapsulation organic layer OL may protect the display element layer DP-OLED from foreign substances such as dust particles.

FIG. 7A is a schematic enlarged view illustrating a first emission area PXA-R, a second emission area PXA-G, and a third emission area PXA-B, and the descriptions of the emission area PXA of FIG. 6 may be substantially equally applied to each of the first to third emission areas PXA-R, PXA-G, and PXA-B.

Referring to FIG. 7A, the display panel DP according to this embodiment may include a base layer BL, a circuit element layer DP-CL, a display element layer DP-OLED, and a thin film encapsulation layer TFL. The display element layer DP-OLED may include light-emitting elements ED1, ED2, and ED3, sacrificial patterns SP1, SP2, and SP3, a pixel defining layer PDL, a partition wall PW, and/or dummy patterns DMP.

The light-emitting elements ED1, ED2, and ED3 may include a first light-emitting element ED1, a second light-emitting element ED2, and a third light-emitting element ED3. The first light-emitting element ED1 may include a first anode AE1, a first emission pattern EP1, and a first cathode CE1. The second light-emitting element ED2 may include a second anode AE2, a second emission pattern EP2, and a second cathode CE2. The third light-emitting element ED3 may include a third anode AE3, a third emission pattern EP3, and a third cathode CE3. The first to third anodes AE1, AE2, and AE3 may be provided in patterns. In an embodiment, the first emission pattern EP1 may provide red light, the second emission pattern EP2 may provide green light, and the third emission pattern EP3 may provide blue light.

First to third light-emitting openings OP1-E, OP2-E, and OP3-E may be defined in the pixel defining layer PDL. The first light-emitting opening OP1-E may expose at least a portion of the first anode AE1. The first emission area PXA-R may be defined as an area exposed by the first light-emitting opening OP1-E, of a top surface of the first anode AE1. The second light-emitting opening OP2-E may expose at least a portion of the second anode AE2. The second emission area PXA-G may be defined as an area exposed by the second light-emitting opening OP2-E, of a top surface of the second anode AE2. The third light-emitting opening OP3-E may expose at least a portion of the third anode AE3. The third emission area PXA-B may be defined as an area exposed by the third light-emitting opening OP3-E, of a top surface of the third anode AE3.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be disposed on top surfaces of the first to third anodes AE1, AE2, and AE3, respectively. First to third sacrificial openings OP1-S, OP2-S, and OP3-S corresponding to the first to third light-emitting openings OP1-E, OP2-E, and OP3-E, respectively, may be defined in the first to third sacrificial patterns SP1, SP2, and SP3.

In this embodiment, first to third partition wall openings OP1-P, OP2-P, and OP3-P corresponding to the first to third light-emitting openings OP1-E, OP2-E and OP3-E, respectively, may be defined in the partition wall PW. Each of the first to third partition wall openings OP1-P, OP2-P, and OP3-P may include the first area A1 (see FIG. 6) and the second area A2 (see FIG. 6), which are described above with reference to FIG. 6. The partition wall PW may include a first partition wall layer L1, an organic film OF, and/or a second partition wall layer L2. The first partition wall layer L1 may include the first outer surface OS1 (see FIG. 7B) of the first side portion S1 (see FIG. 7B) defining the first areas A1 (see FIG. 6) of the first to third partition wall openings OP1-P, OP2-P, and OP3-P and the second outer surface OS2 (see FIG. 7B) of the second portion P2 defining portions of the second areas A2 (see FIG. 6). The second partition wall layer L2 may include the third outer surface OS3 (see FIG. 7B) defining remaining portions of the second areas A2 (see FIG. 6) of the first to third partition wall openings OP1-P, OP2-P, and OP3-P.

The first emission pattern EP1 and the first cathode CE1 may be disposed in the first partition wall opening OP1-P, the second emission pattern EP2 and the second cathode CE2 may be disposed in the second partition wall opening OP2-P, and the third emission pattern EP3 and the third cathode CE3 may be disposed in the third partition wall opening OP3-P. Each of the first to third cathodes CE1, CE2, and CE3 may contact the first side portion S1 of the first partition wall layer L1 (FIG. 7B).

In this embodiment, the first to third cathodes CE1, CE2, and CE3 may be physically separated from the second portion P2 (FIG. 7B) of the first partition wall layer L1 defining the tip part by the second partition wall layer L2 and be respectively disposed in the light-emitting openings OP1-E, OP2-E, and OP3-E and may contact the first side portion S1 (see FIG. 7B) of the first partition wall layer L1 so as to be electrically connected to each other, thereby receiving a common voltage. The first partition wall layer L1 which contacts each of the first to third cathodes CE1, CE2, and CE3, may have relatively high electrical conductivity than that of the second partition wall layer L2, and thus, contact resistance with the first to third cathodes CE1, CE2, and CE3 may be reduced. Thus, a common cathode voltage may be uniformly provided to the emission areas PXA-R, PXA-G, and PXA-B.

According to the disclosure, the emission patterns EP1, EP2, and EP3 may be patterned and deposited in pixel units by the tip parts defined on the partition walls PW. For example, the emission patterns EP1, EP2, and EP3 may be commonly formed using an open mask, and may be readily divided into pixel units by the partition wall PW.

On the other hand, when patterning the emission patterns EP1, EP2, and EP3 using a fine metal mask (FMM), a support spacer protruding from the conductive partition wall to support the fine metal mask may have to be provided. Since the fine metal mask is spaced apart from the base surface, on which the patterning is performed, by heights of the partition wall and the spacer, implementation of high resolution may be limited. As the fine metal mask contacts the spacer, foreign substances may remain on the spacer after the patterning process of the emission patterns EP1, EP2, and EP3, or the spacer may be damaged by being stabbed by the fine metal mask. Thus, defective display panels may occur.

According to this embodiment, the physical separation between the light-emitting elements ED1, ED2, and ED3 may be readily achieved by providing the partition wall PW. Thus, current leakage or driving errors between the adjacent emission areas PXA-R, PXA-G, and PXA-B may be prevented from occurring, and independent driving of each of the light-emitting elements ED1, ED2, and ED3 may be possible.

Particularly, the emission patterns EP1, EP2, and EP3 may be patterned without a mask that contacts the internal configuration within the display area DA (see FIG. 2A) to reduce the defect rate, thereby providing the display panel DP having improved process reliability. As the patterning is possible even if the separate support spacer protruding from the partition wall PW is not provided, each of the emission areas PXA-R, PXA-G, and PXA-B may be miniaturized to provide the display panel DP in which high resolution may be easily implemented.

In manufacturing the large-area display panel DP, the process cost may be reduced by omitting the process of manufacturing the large-area mask, and the display panel DP may not be affected by defects that may occur in the large-area mask, and thus, the display panel DP with improved process reliability may be provided.

Capping patterns CP1, CP2, and CP3 may include a first capping pattern CP1, a second capping pattern CP2, and a third capping pattern CP3. The first to third capping patterns CP1, CP2, and CP3 may be disposed on the first to third cathodes CE1, CE2, and CE3, respectively, and also may be disposed in the first to third partition wall openings OP1-P and OP2-P, and OP3-P, respectively.

The dummy patterns DMP may include first dummy patterns D1, second dummy patterns D2, and third dummy patterns D3.

The first dummy patterns D1 may include first-1 to first-3 dummy patterns D11, D12, and D13, which surround the first to third emission areas PXA-R, PXA-G, and PXA-B on a plane, respectively. The first-1 to first-3 dummy patterns D11, D12, and D13 and the first to third light-emitting patterns EP1, EP2, and EP3 may include a same material, respectively, and thus may be formed through a same process.

The second dummy patterns D2 may include second-1 to second-3 dummy patterns D21, D22, and D23, which surround the first to third emission areas PXA-R, PXA-G, and PXA-B on a plane, respectively. The second-1 to second-3 dummy patterns D21, D22, and D23 and the first to third cathodes CE1, CE2, and CE3 may include a same material, respectively, and thus may be formed through a same process.

The third dummy patterns D3 may include third-1 to third-3 dummy patterns D31, D32, and D33, which surround the first to third emission areas PXA-R, PXA-G, and PXA-B on a plane, respectively. The third-1 to third-3 dummy patterns D31, D32, and D33 and the first to third capping patterns CP1, CP2, and CP3 may include a same material, respectively, and thus may be formed through a same process.

First to third dummy openings OP1-D, OP2-D, and OP3-D respectively corresponding to the first to third light-emitting openings OP1-E, OP2-E, and OP3-E) may be defined in the dummy pattern DMP. The first dummy opening OP1-D may be defined by inner surfaces of the first-1, second-1, and third-1 dummy patterns D11, D21, and D31, the second dummy opening OP2-D may be defined by inner surfaces of the first-2, second-2, and third-2 dummy patterns D12, D22, and D32, and the third dummy opening OP3-D may be defined by inner surfaces of the first-3, second-3, and third-3 dummy patterns D13, D23, and D33.

The thin film encapsulation layer TFE may include lower encapsulation inorganic patterns LIL1, LIL2, and LIL3, an encapsulation organic layer OL, and an upper encapsulation inorganic layer UIL. In this embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first to third lower encapsulation inorganic patterns LIL1, LIL2, and LIL3 may correspond to the first to third light-emitting openings OP1-E, OP2-E, and OP3-E, respectively.

The first lower encapsulation inorganic pattern LIL1 may cover the first light-emitting element ED1 and the first-1, second-1, and third-1 dummy patterns D11, D21, and D31 so that a portion of the first lower encapsulation inorganic pattern LIL1 is disposed inside the first partition wall opening OP1-P. The second lower encapsulation inorganic pattern LIL2 may cover the second light-emitting element ED2 and the first-2, second-2, and third-2 dummy patterns D12, D22, and D32, so that a portion of the second lower encapsulation inorganic pattern LIL2 is disposed inside the second partition wall openings OP2-P. The third lower encapsulation inorganic pattern LIL3 may cover the third light-emitting element ED3 and the first-3, second-3, and third-3 dummy patterns D13, D23, and D33 so that a portion of the third lower encapsulation inorganic pattern LIL3 is disposed inside the third partition wall opening OP3-P. The first to third lower encapsulation inorganic patterns LIL1, LIL2, and LIL3 may be provided in the form of patterns spaced apart from each other.

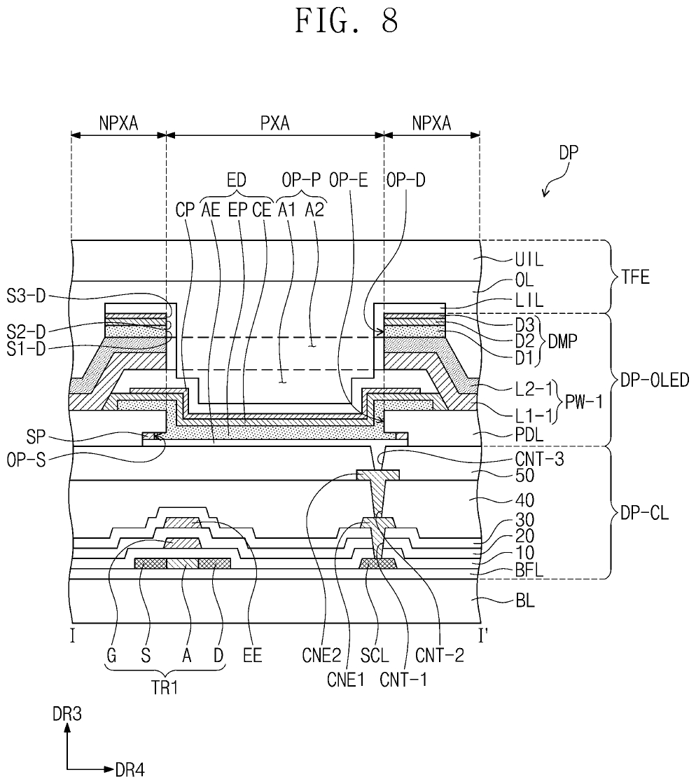

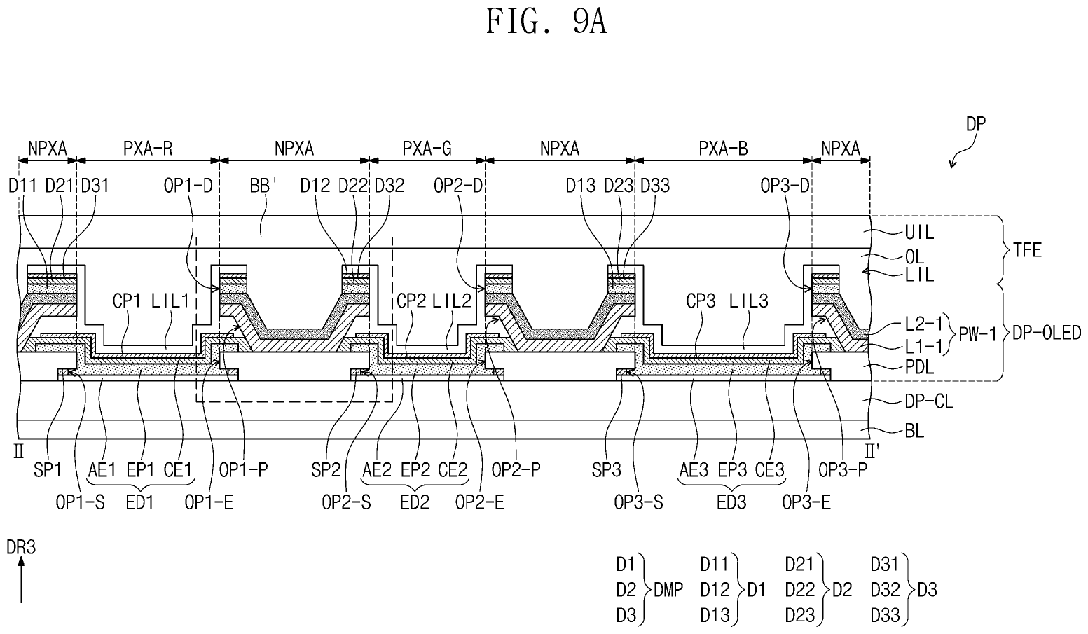

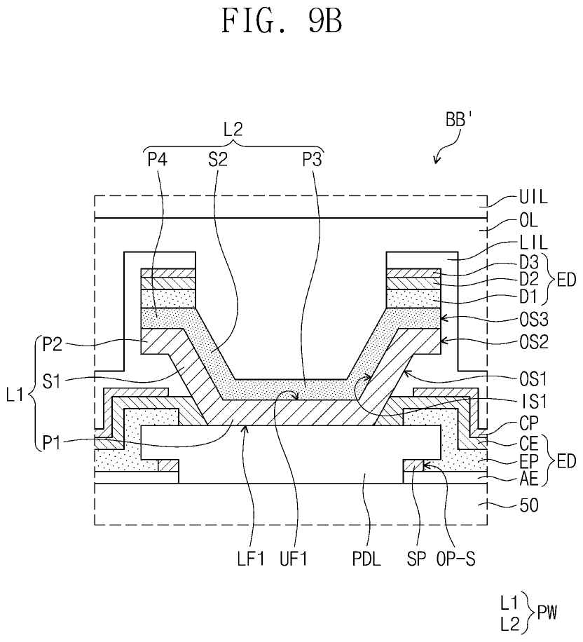

FIGS. 8 and 9A are schematic cross-sectional views of the display panel according to an embodiment of the disclosure. FIG. 8 is a schematic cross-sectional view taken along line I-I′ of FIG. 5. FIG. 9A is a schematic cross-sectional view taken along line II-II′ of FIG. 5. FIG. 9B is a schematic enlarged view of area BB′ of FIG. 9A. Hereinafter, in describing the display panel according to an embodiment of the disclosure with reference to FIGS. 8, 9A, and 9B, the same reference numerals are given to the components described above in FIGS. 6, 7A, and 7B, and detailed description thereof is omitted.

Referring to FIGS. 8, 9A, and 9B, the display panel according to an embodiment may be different from the display panel illustrated in FIG. 6 in that the organic film OF is omitted from the partition wall PW-1. The second partition wall layer L2-1 may be directly disposed on the first partition wall layer L1-1. The second partition wall layer L2-1 may have a shape extending along the second portion P2, the first side portion S1, and the first portion P1 of the first partition wall layer L1-1. Thus, the second partition wall layer L2-1 may have a groove shape that is recessed by a height difference (e.g., a predetermined or selectable height difference) in the third direction DR3.

The second partition wall layer L2-1 may include a third portion P3 disposed on the first portion P1 of the first partition wall layer L1-1, a fourth portion P4 spaced apart from the first portion P1 and having a height difference with respect to the third portion P3, and a second side portion S2 connecting the third portion P3 to the fourth portion P4. The third portion P3 of the second partition wall layer L2-1 may be directly disposed on the first portion P1 of the first partition wall layer L1-1. The fourth portion P4 may have a height difference with respect to the third portion P3 in the third direction DR3 and may be spaced apart from the third portion P3. The fourth portion P4 may be directly disposed on the second portion P2 of the first partition wall layer L1-1. The second side portion S2 may connect the third portion P3 to the fourth portion P4.

Thicknesses of the third portion P3 and the fourth portion P4 may be substantially the same. However, the embodiments are not limited thereto, and the third portion P3 and the fourth portion P4 may have thicknesses different from each other. In an embodiment, the thickness of each of the third portion P3 and the fourth portion P4 may be about 1,000 Å to about 2,000 Å. The thickness of the third portion P3 may be defined as a height difference between a bottom surface of the third portion P3 and a top surface of the third portion P3. The thickness of the fourth portion P4 may be defined as a height difference between a bottom surface of the fourth portion P4 and a top surface of the fourth portion P4.

In an embodiment, the outer surface OS2 of the second portion P2 of the first partition wall layer L1-1 and the outer surface OS3 of the third portion P3 of the second partition wall layer L2-1 may be aligned with each other in the third direction DR3. The third portion P3 of the second partition wall layer L2-1 may provide the tip part disposed on the partition wall PW together with the first portion P1 of the first partition wall layer L1-1.

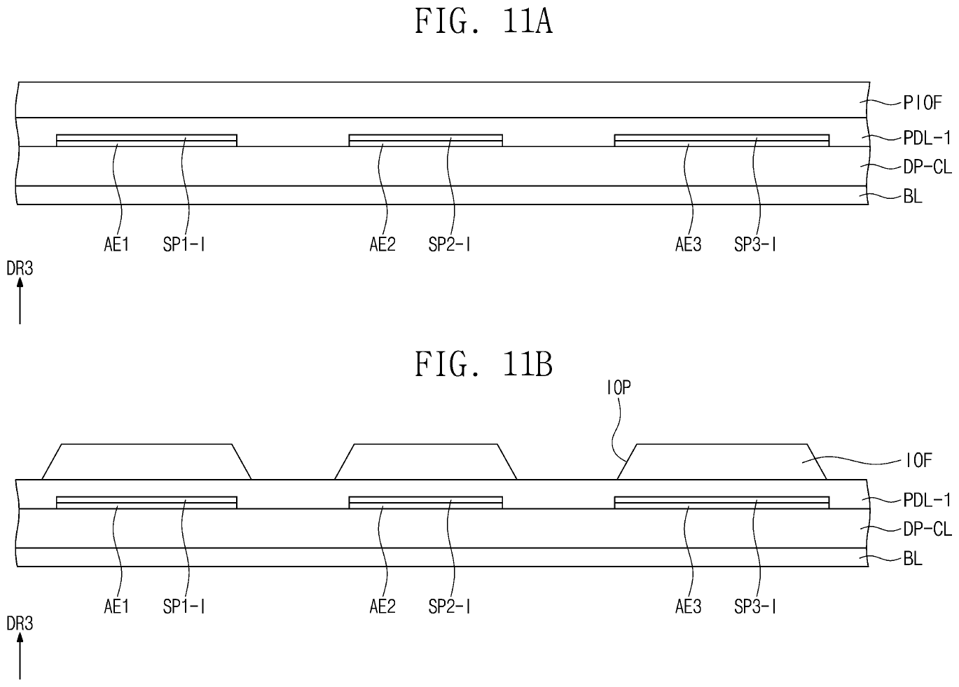

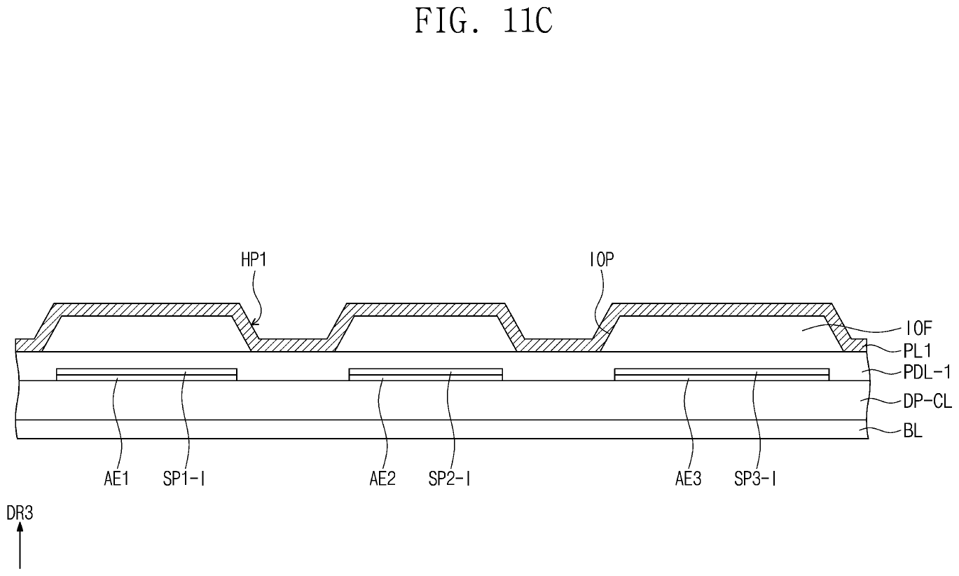

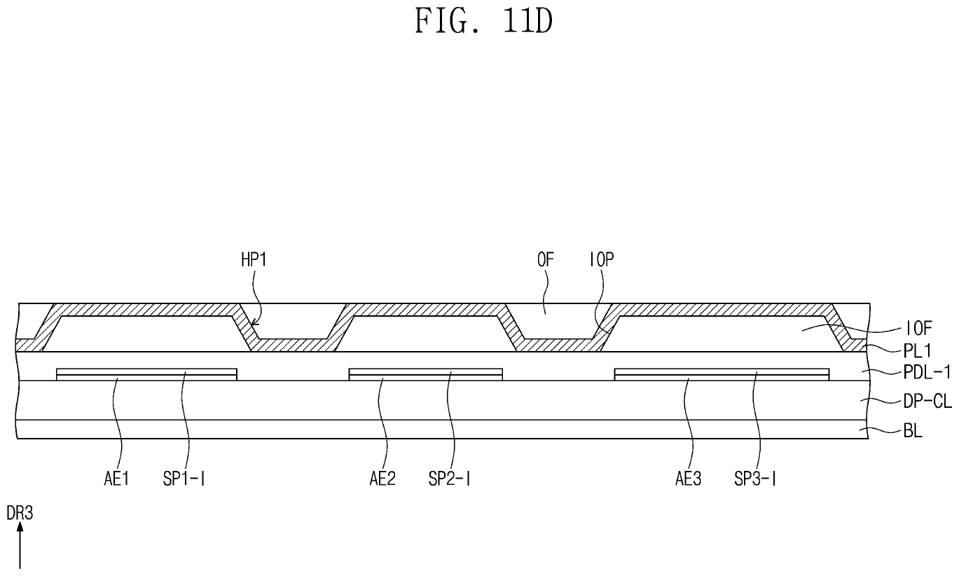

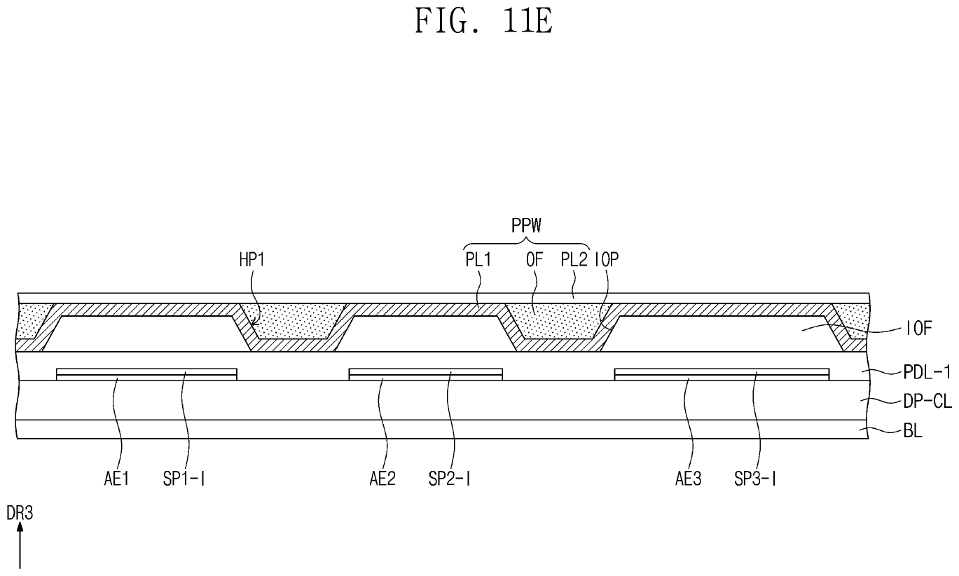

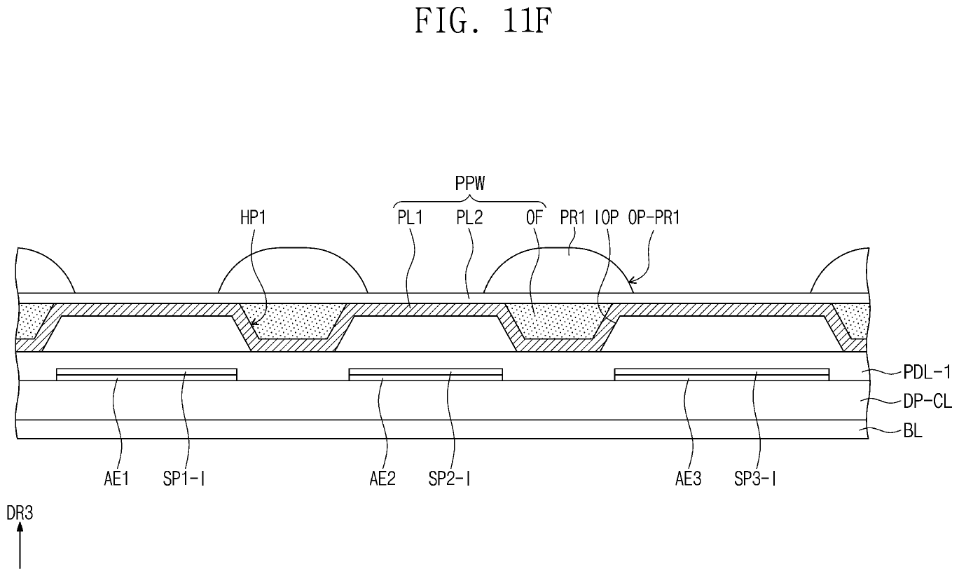

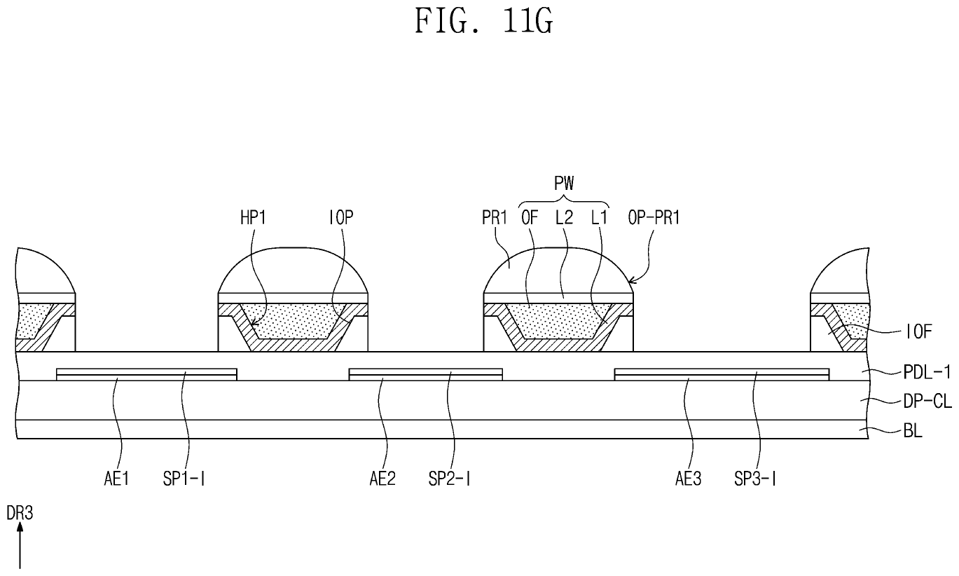

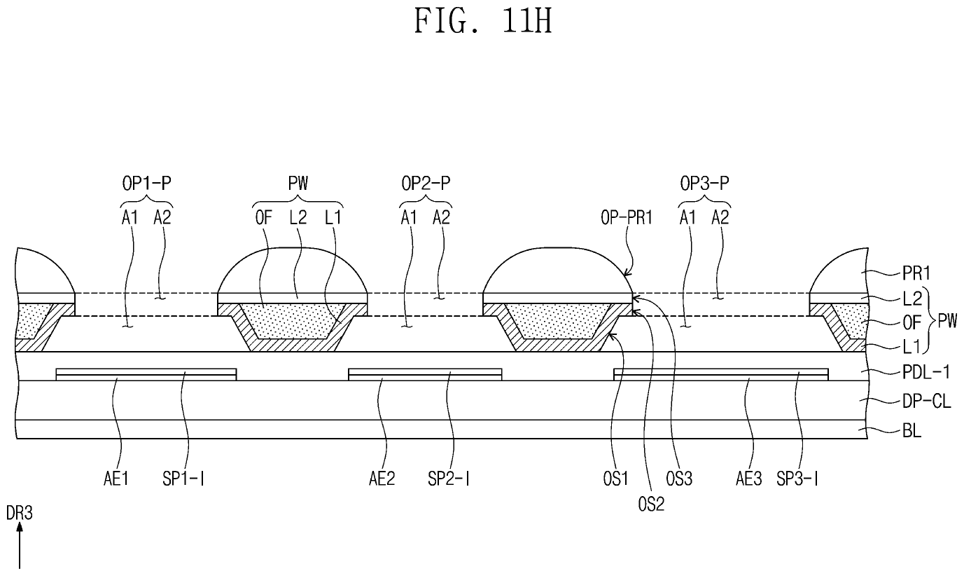

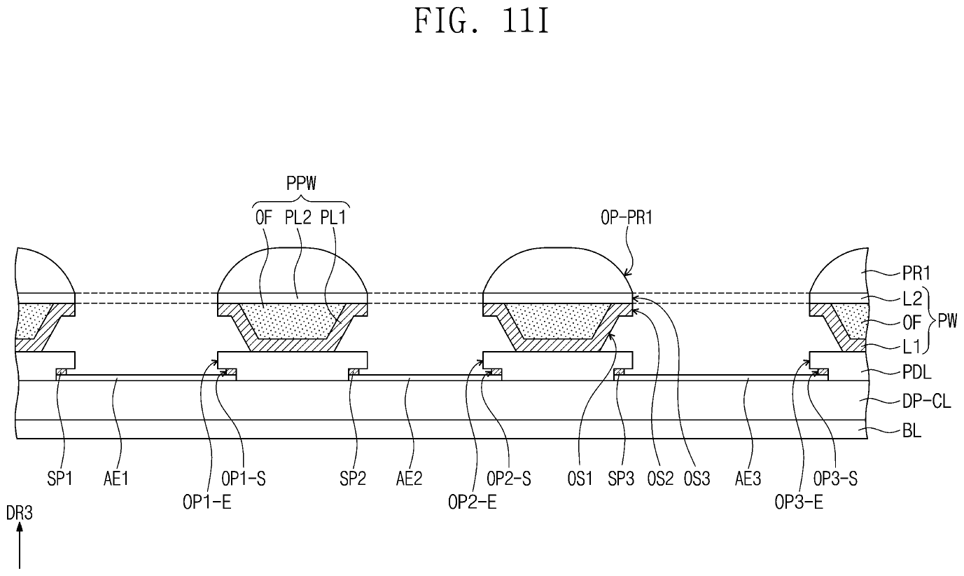

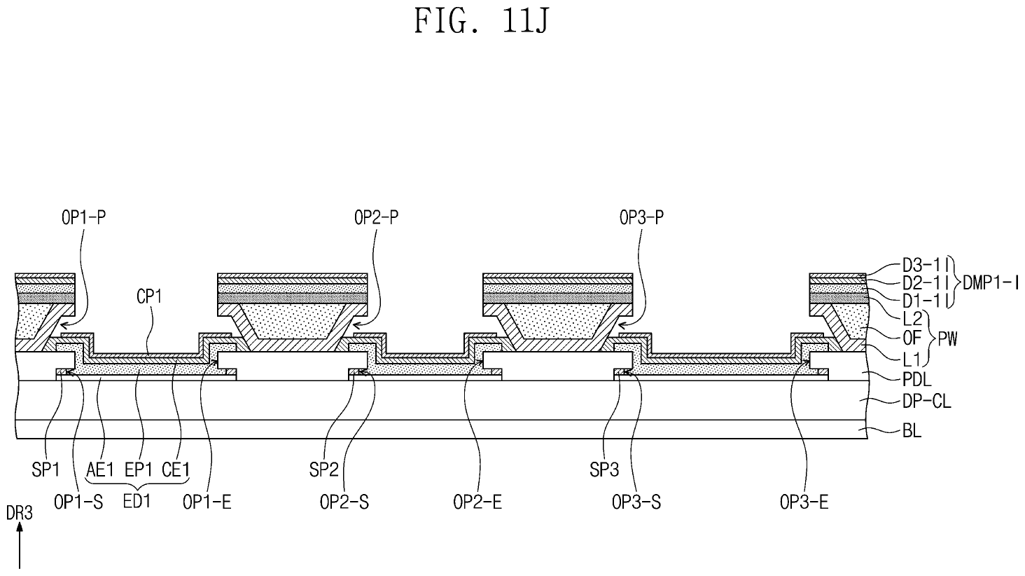

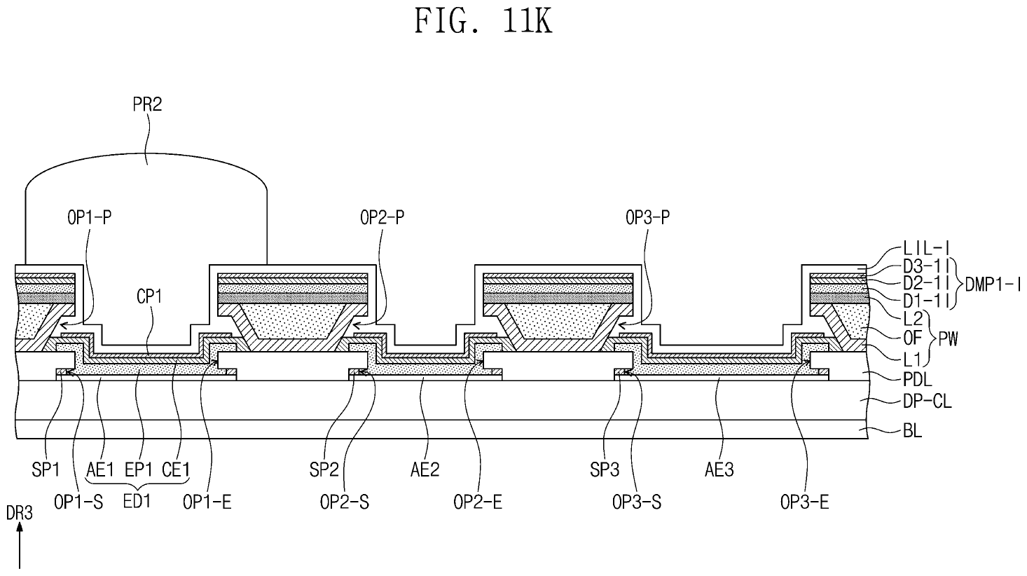

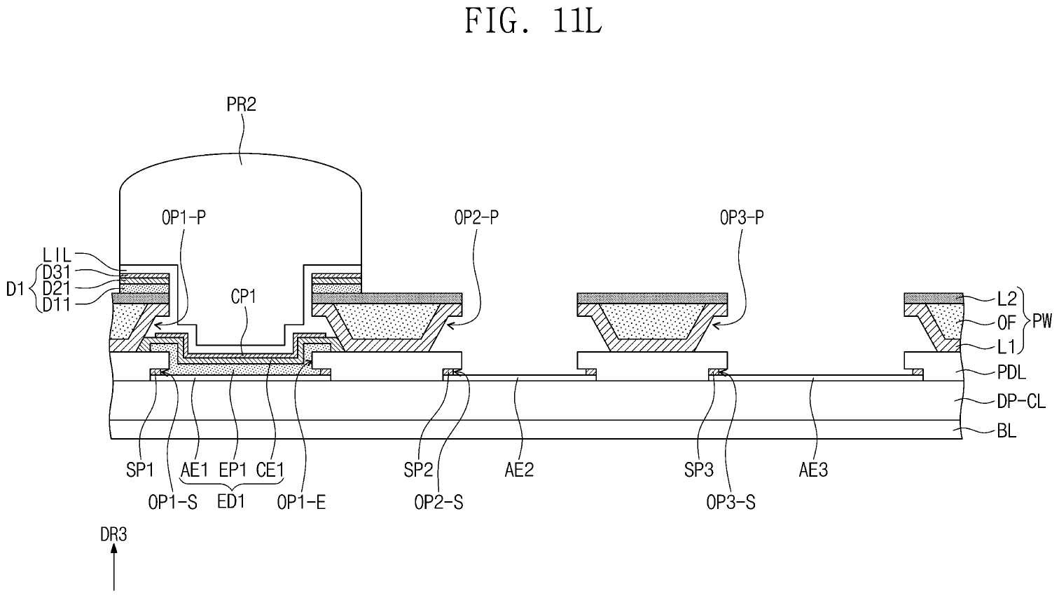

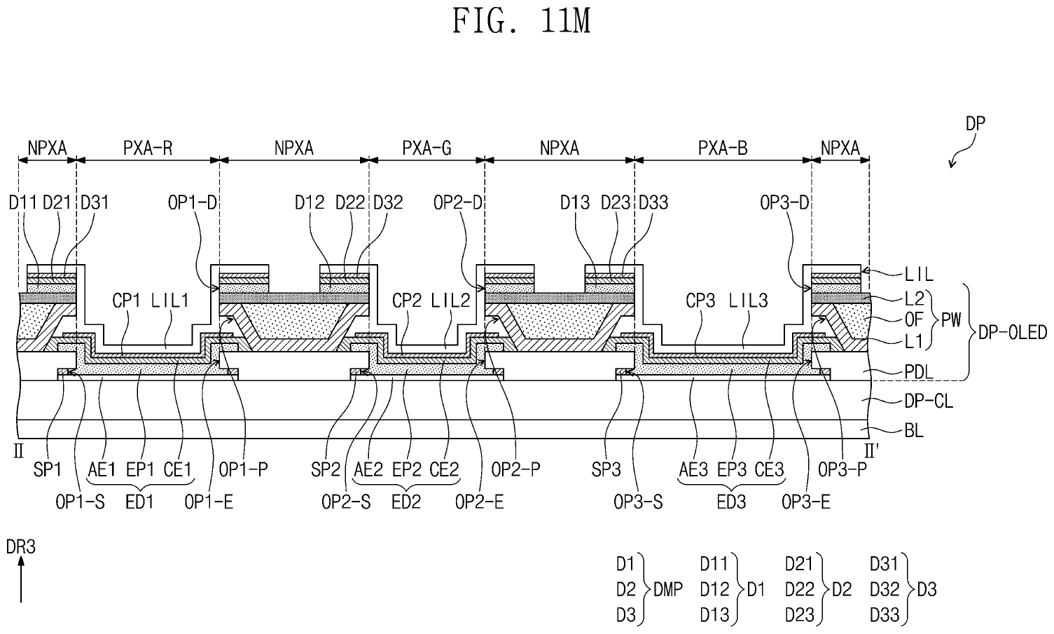

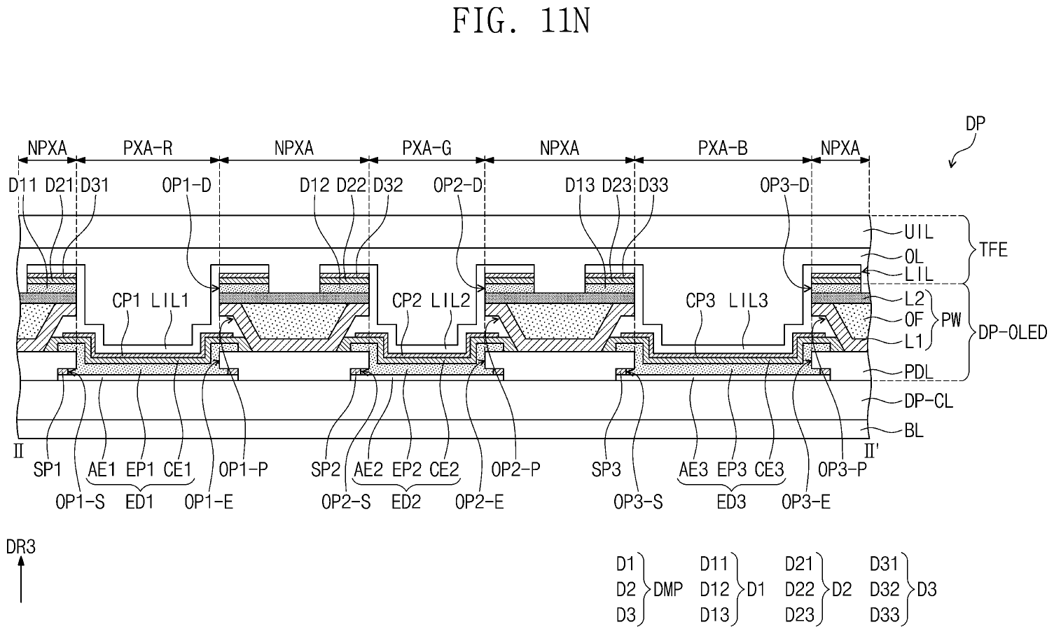

FIGS. 11A to 11N are schematic cross-sectional views illustrating some processes of a method for manufacturing a display panel according to an embodiment of the disclosure. In description of FIGS. 11A to 11N, the same/similar reference numerals are used for the same/similar components with reference to FIGS. 1A to 9B, and duplicated descriptions will be omitted.

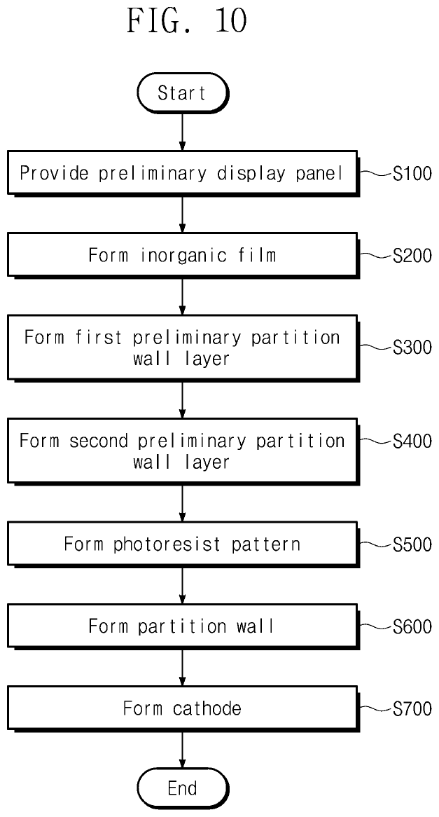

Referring to FIG. 10, the method for manufacturing the display panel according to an embodiment of the disclosure may include a process (S100) of providing a preliminary display panel, a process (S200) of forming an inorganic film, a process (S300) of forming a first preliminary partition wall layer, a process (S400) of forming a second preliminary partition wall layer, a process (S500) of forming a photoresist pattern, a process (S600) of forming a partition wall, and a process (S700) of forming a cathode.

Referring to FIG. 11A, the method for manufacturing the display panel according to this embodiment may include the process (S100) of providing the preliminary display panel. The preliminary display panel provided in this embodiment may include a base layer BL, a circuit element layer DP-CL, first to third anodes AE1, AE2, and AE3, and first to third preliminary sacrificial patterns SP1-I, SP2-I, and SP3-I, and a preliminary pixel defining layer PDL-1.

The circuit element layer DP-CL may be formed through a process of manufacturing a typical circuit element in which an insulating layer, a semiconductor layer, and a conductive layer are formed through a method such as coating or deposition and are selectively patterned by a photolithography and etching process to form a semiconductor pattern, a conductive pattern, a signal line, and the like.

The first anode AE1 and the first preliminary sacrificial pattern SP1-I may be formed by the same patterning process, the second anode AE2 and the second preliminary sacrificial pattern SP2-I may be formed by the same patterning process, and the third anode AE3 and the third preliminary sacrificial pattern SP3-I may be formed by the same patterning process.

The preliminary pixel defining layer PDL-1 may be disposed on the base layer BL. The preliminary pixel defining layer PDL-1 may cover all of the first to second anodes AE1, AE2, and AE3 and the first to third preliminary sacrificial patterns SP1-I, SP2-I, and SP3-I.

Referring to FIGS. 11A and 11B, the method for manufacturing the display panel according to this embodiment may include the process (S200) of forming an inorganic film IOF on the preliminary display panel. The process of forming the inorganic film IOF may include a process of forming a preliminary inorganic film PIOF on the preliminary pixel defining film PDL-1 and a process of patterning the preliminary inorganic film PIOF to form the inorganic film IOF in which an opening IOP, through which a top surface of the preliminary pixel defining film PDL-1 is exposed, is defined.

Referring to FIG. 11A, the preliminary inorganic film PIOF may overlap the first to third anodes AE1, AE2, and AE3. The process of forming the preliminary inorganic film PIOF may be carried out as a deposition process of an inorganic material. The preliminary inorganic film PIOF may be formed on the preliminary pixel defining layer PDL-1 by depositing the inorganic material on the preliminary pixel defining layer PDL-1. The inorganic material for forming the preliminary inorganic film PIOF may include a material composed of silicon (Si) and at least one selected from the group consisting of oxygen (O), nitrogen (N), carbon (C), and hydrogen (H). The inorganic material for forming the preliminary inorganic film PIOF may include at least one of silicon oxide (SiOₓ), silicon nitride (SiNₓ), silicon oxynitride (SiOₓN_{y}), silicon carbonitride (SiCN), silicon carbonate (SiOC), and silicon carbonate (SiCON). For example, the inorganic material forming the preliminary inorganic film PIOF may include silicon nitride (SiNₓ).

Referring to FIG. 11B, the process (S200) of forming the inorganic film IOF by etching the preliminary inorganic film PIOF may be performed. The inorganic film IOF having an opening IOP defined therein may be formed by removing an area of the preliminary inorganic film PIOF by a method such as etching or the like. The opening IOP may be formed to pass through the inorganic film IOF so as to expose a portion of the top surface of the preliminary pixel defining layer PDL-1. FIGS. 11A and 11B illustrate an example in which the inorganic film IOF is formed through the etching process, but the embodiments are not limited thereto, and the inorganic film IOF may be formed to have an opening IOP when manufacturing the inorganic film IOF.

The inorganic film IOF may overlap each of the first to third anodes AE1, AE2, and AE3 on a plane. The opening IOP formed in the inorganic film IOF may not overlap each of the first to third anodes AE1, AE2, and AE3. However, it is not limited thereto, and the opening IOP may overlap at least some of the first to third anodes AE1, AE2, and AE3.

An inner surface of the inorganic film IOF defining the opening IOP may be formed to have an inclination. For example, an inner surface of the inorganic film IOF may be an inclined surface. The opening IOP may have a shape of which a width gradually increases from the bottom surface of the inorganic film IOF to the top surface of the inorganic film IOF. An inner surface of the inorganic film IOF may be formed at an acute angle with respect to the top surface of the preliminary pixel defining layer PDL-1. However, the shape of the inner surface of the inorganic film IOF is not limited thereto. Unlike the configuration illustrated in FIG. 11B, the inner surface of the inorganic film IOF may be formed to have a stair shape or be formed at a right angle with respect to the top surface of the preliminary pixel defining layer PDL-1.

The words that the inner surface of the inorganic film IOF has an inclination may mean that a cross-section formed through the inorganic film IOF disposed on the preliminary pixel defining layer PDL-1 has an inclination. To form the inclined surface, a halftone mask or a slit mask may be used in the process of patterning the inorganic film IOF, but the embodiments are not limited thereto. As the inner surface of the inorganic film IOF is formed to have an inclination, the inner surface of the opening IOP may be readily covered by a first preliminary partition wall layer PL1 in case that the first preliminary partition wall layer PL1 is formed.

Referring to FIG. 11C, the method for manufacturing the display panel according to an embodiment of the disclosure may include a process (S300) of forming the first preliminary partition wall layer PL1 on the inorganic film IOF. After forming the inorganic film IOF, a process of forming the first preliminary partition wall layer PL1 including a transparent conductive material on the inorganic film IOF may be performed. The process of forming the first preliminary partition wall layer PL1 may be performed as a deposition process of the transparent conductive material. In this embodiment, the transparent conductive material forming the first preliminary partition wall layer PL1 may include transparent conductive oxide (TCO) such as indium tin oxide (ITO), indium zinc oxide (IZO), indium gallium zinc oxide (IGZO), indium zinc tin oxide (IZTO), zinc oxide (ZnO), or indium oxide (In₂O₃). The transparent conductive material forming the first preliminary partition wall layer PL1 may be indium tin oxide.

The first preliminary partition wall layer PL1 may be disposed on the inorganic film IOF and the preliminary pixel defining layer PDL-1. The first preliminary partition wall layer PL1 may be formed to overlap at least the opening IOP. The first preliminary partition wall layer PL1 may be formed along the top surface of the inorganic film IOF, the inner surface of the inorganic film IOF, and the top surface of the preliminary pixel defining layer PDL-1 exposed through the opening IOP.

The first preliminary partition wall layer PL1 may have a groove shape that is recessed by a height difference (e.g., a predetermined or selectable height difference) in the third direction DR3 at a portion of the first preliminary partition wall layer PL1 overlapping the opening IOP. In the first preliminary partition wall layer PL1, a first groove HP1 having a shape that is recessed toward the base layer BL from a reference plane corresponding to the top surface of the inorganic film IOF may be formed in a portion overlapping the opening IOP.

Referring to FIG. 11D, the method for manufacturing the display panel according to an embodiment of the disclosure may further include a process of forming an organic film OF on the first preliminary partition wall layer PL1. The organic film OF may be disposed in the first groove HP1 formed in the first preliminary partition wall layer PL1.

The process of forming the organic film OF may include a process of providing an organic material into the first groove HP1 formed in the first preliminary partition wall layer PL1. The process of forming the organic film OF may further include a process of curing the organic material provided in the first groove HP1. The organic film OF may be disposed in the first groove HP1 to serve to improve mechanical strength of the partition wall PW (see FIG. 11H), which is subsequently formed, and thus may be used without restriction as long as the organic film OF does not affect the light transmittance of the partition wall PW after the curing. For example, the organic material for forming the organic film OF may include an acrylic-based resin, a methacrylic-based resin, a polyisoprene-based resin, a vinyl-based resin, an epoxy-based resin, a urethane-based resin, a cellulose-based resin, a, siloxane-based resin, a polyimide-based resin, a polyamide-based resin, or a perylene-based resin. For example, the organic material for forming the organic film OF may include polyimide (Pl) or polyethylene terephthalate (PET).

The organic film OF may be formed by providing the organic material for forming the organic film OF in the first groove HP1 and thermally curing or photocuring the organic material. The organic material provided in the first groove HP1 may be in a liquid form before the curing. For example, the organic film OF may be formed by providing a liquid polymer resin to the first groove HP1 and curing the liquid polymer resin provided in the first groove HP1 with ultraviolet rays. The polymer resin for forming the organic film OF may be provided in the first groove HP1, and heat or light may be applied to the provided polymer resin to finally form the organic film OF. The polymer resin for forming the organic film OF may be provided in various manners. For example, the polymer resin may be provided by a method such as an inkjet printing method or a dispensing method.

The organic film OF may be filled into the first groove HP1. The organic film OF may be entirely filled into the first groove HP1. However, the embodiment of the disclosure is not limited thereto, and the organic film OF may be partially filled into the first groove HP1.

Referring to FIG. 11F, the method for manufacturing the display panel according to an embodiment of the disclosure may include the process (S400) of forming a second preliminary partition wall layer PL2 on the first preliminary partition wall layer PL1 to form a preliminary partition wall PPW.

The process of forming the second preliminary partition wall layer PL2 may be performed through a deposition process using a conductive material. In an embodiment, the conductive material forming the second preliminary partition wall layer PL2 may be a metal material. For example, the conductive material forming the second preliminary partition wall layer PL2 may include gold (Au), silver (Ag), aluminum (Al), magnesium (Mg), lithium (Li), molybdenum (Mo), titanium (Ti), copper (Cu), or an alloy thereof. The metal forming the second preliminary partition wall layer PL2 may be, for example, titanium (Ti).

In an embodiment, the second preliminary partition wall layer PL2 may not include a metal material. The second preliminary partition wall layer PL2 may be formed of a silicon-based compound. For example, the second preliminary partition wall layer PL2 may include at least one of silicon oxide (SiOₓ), silicon nitride (SiNₓ), and silicon oxynitride (SiOₓN_{y}). For example, the second preliminary partition wall layer PL2 may include silicon oxide (SiOₓ).

The second preliminary partition wall layer PL2 may be disposed on the first preliminary partition wall layer PL1 and the organic film OF. As the organic film OF is disposed in the first groove HP1 of the first preliminary partition wall layer PL1, the second preliminary partition wall layer PL2 may be formed to have a flat shape on the first preliminary partition wall layer PL1. However, the embodiment of the disclosure is not limited thereto, and in case that the organic film OF is disposed while being partially filled into the first groove HP1, the second preliminary partition wall layer PL2 may be formed to have a shape that is recessed by a height difference (e.g., a predetermined or selectable height difference) in the third direction DR3 at a portion of the second preliminary partition wall layer PL2 overlapping the opening IOP.

In the process of forming the second preliminary partition wall layer PL2, the preliminary partition wall PPW including the first preliminary partition wall layer PL1, the organic film OF, and the second preliminary partition wall layer PL2 may be formed.

Referring to FIG. 11F, the method for manufacturing the display panel according to an embodiment of the disclosure may include the process (S500) of forming a first photoresist pattern PR1 on the preliminary partition wall PPW. The first photoresist pattern PR1 may be formed by forming a preliminary photoresist layer on the preliminary partition wall PPW and patterning the preliminary photoresist layer using a photo mask. A photo opening OP-PR1 may be formed in the first photoresist pattern PR1 through a patterning process. The photo opening OP-PR1 may overlap the first to third anodes AE1, AE2, and AE3.

The first photoresist pattern PR1 may overlap the opening OP on a plane. On the plane, the first photoresist pattern PR1 may entirely overlap the opening IOP. A planar area of the first photoresist pattern PR1 may be greater than that of the opening IOP. For example, a planar area of a bottom surface of the first photoresist pattern PR1 may be greater than that of the uppermost end of the opening IOP. The bottom surface of the first photoresist pattern PR1 may partially overlap the top surface of the inorganic film IOF on the plane. Thus, in a process of etching the inorganic film IOF, the first preliminary partition wall layer PL1, and the second preliminary partition wall layer PL2, which is described below, portions of the first and second preliminary partition wall layers PL1 and PL2 disposed on the top surface of the inorganic film IOF may remain after the etching process. The portions of the first and second preliminary partition wall layers PL1 and PL2, which remain after the etching process, may form tip parts on the partition wall PW to be formed below.

Referring to FIGS. 11F to 11H, the method for manufacturing the display panel according to an embodiment of the disclosure may include the process (S500) of etching the inorganic film IOF, the first preliminary partition wall layer PL1, and the second preliminary partition wall layer PL2 to form the partition wall PW in which the partition wall openings OP1-P, OP2-P, and OP3-P are defined. The process (S500) of forming the partition wall may include a process of primarily etching the inorganic film IOF, the first preliminary partition wall layer PL1, and the second preliminary partition wall layer PL2 and a process of secondarily etching the inorganic film IOF.

Referring to FIGS. 11F and 11G, the process of primarily etching the inorganic film IOF, the first preliminary partition wall layer PL1, and the second preliminary partition wall layer PL2 may include a process of etching the inorganic film IOF, the first preliminary partition wall layer PL1, and the second preliminary partition wall layer PL2 by using the first photoresist pattern PR1 as a mask.

The process of primarily etching the first preliminary partition wall layer PL1 and the second preliminary partition wall layer PL2 may include a process of dry-etching or wet-etching the first preliminary partition wall layer PL1 and the second preliminary partition wall layer PL2 by using the first photoresist pattern PR1 as a mask. In an embodiment, the process of primarily etching the inorganic film IOF, the first preliminary partition wall layer PL1, and the second preliminary partition wall layer PL2 may include a process of dry-etching the inorganic film IOF, the first preliminary partition wall layer PL1, and the second preliminary partition wall layer PL2. As another example, the process of primarily etching the inorganic film IOF, the first preliminary partition wall layer PL1, and the second preliminary partition wall layer PL2 may be performed twice. For example, the process of etching the inorganic film IOF, the first preliminary partition wall layer PL1, and the second preliminary partition wall layer PL2 may include a dry etching process and a wet etching process, which are performed sequentially.

The primary etching process in this embodiment may be performed under an etching environment in which etching selectivity between the inorganic film IOF, the first preliminary partition wall layer PL1, and the second preliminary partition wall layer PL2 are substantially the same. Thus, the second outer surface OS2 (see FIG. 7B) of the second portion P2 (see FIG. 7B) of the first partition wall layer L1 (see FIG. 7B) and the third outer surface OS3 (see FIG. 7B) of the second partition wall layer L2 (see FIG. 7B), which define the partition wall openings OP1-P, OP2-P, and OP3-P, may be substantially aligned with each other.

Referring to FIG. 11H, after the process of primarily etching the inorganic film IOF, the first preliminary partition wall layer PL1, and the second preliminary partition wall layer PL2, the process of secondarily etching the inorganic film IOF may be performed. The process of secondarily etching the inorganic film IOF may include a process of dry-etching the inorganic film IOF by using the first photoresist pattern PR1 as a mask to remove the inorganic film IOF. The dry etching may be performed in plasma etching equipment. Methods such as ion beam etching, inductively coupled plasma etching, and reactive ion etching may be applied as the plasma etching.

The secondary etching process in this embodiment may be performed under an environment in which the etching selectivity between the inorganic film IOF and the first and second preliminary partition wall layers PL1 and PL2 is high. An etching rate of the inorganic film IOF may be higher than that of each of the first and second preliminary partition wall layers PL1 and PL2. Thus, the inorganic film IOF may be more etched than each of the first preliminary partition wall layer PL1 and the second preliminary partition wall layer PL2, and thus, in the partition wall PW to be formed below, the inorganic film IOF may be removed to expose the first side portion S1 (see FIG. 7B) of the first partition wall layer L1.

In an embodiment, the inorganic film IOF and each of the first and second preliminary partition wall layers PL1 and PL2 may include different materials. The inorganic film IOF may include a material having high etch selectivity with respect to each of the first and second preliminary partition wall layers PL1 and PL2. For example, the inorganic film IOF may include silicon nitride (SiNₓ), the first preliminary partition wall layer PL1 may include indium tin oxide, and the second preliminary partition wall layer PL2 may include silicon oxide (SiOₓ).

The process of secondarily etching the inorganic film IOF may include a process of dry-etching the inorganic film IOF by using the first photoresist pattern PR1 as a mask. The dry etching may be performed using etching selectivity between the inorganic film IOF and each of the first and second preliminary partition wall layers PL1 and PL2. The inorganic film IOF may be selectively removed using the etching selectivity between the inorganic film IOF and each of the first and second preliminary partition wall layers PL1 and PL2. In case that the inorganic film IOF and the first preliminary partition wall layer PL1 or the second preliminary partition wall layer PL2 is made of a same material, in the process of secondarily etching the inorganic film IOF, a portion of the first preliminary partition wall layer PL1 or the second preliminary partition wall layer PL2 may be removed together. However, as in the disclosure, since the inorganic film IOF and each of the first and second preliminary partition wall layers PL1 and PL2 are made of different materials, the first and second preliminary partition wall layers PL1 and PL2 may be maintained without being etched due to the etch selectivity, and the inorganic film IOF may be etched and removed.

The process of secondarily etching the inorganic film may include a process of selectively etching the inorganic film using reactive radicals generated from plasma of a process gas. As the process gas used in the dry etching process, at least one gas selected from the group consisting of SiF₄, CF₄, C₃F₈, C₂F₆, CHF₃, CClF₃, O₂, NF₃, and SF₆ may be used. The process gas may further include an inert gas such as Ar or N₂ that does not directly participate in the etching reaction to increase etching reactivity or etching uniformity.

In case that the plasma of the process gas is supplied into a reaction chamber using plasma etching equipment, the inorganic film IOF may be etched by reactive radicals generated from the plasma, and the first preliminary partition wall layer PL1 and the second preliminary partition wall layer PL2 may not be relatively etched. For example, in case that the inorganic film IOF includes silicon nitride (SiNₓ), the first preliminary partition wall layer PL1 may include a transparent conductive oxide, and the second preliminary partition wall layer PL2 may include silicon oxide (SiOₓ), the first and second preliminary partition wall layers PL1 and PL2 may be maintained, and the inorganic film IOF including the silicon nitride (SiNₓ) may be selectively removed, using different etching characteristics between silicon oxide (SiOₓ), transparent conductive oxide, and silicon nitride (SiNₓ). To increase etch selectivity of the inorganic film IOF with respect to the first and second preliminary partition wall layers PL1 and PL2, process conditions such as a process gas, a process pressure, and a process temperature may be appropriately adjusted.

Referring again to FIG. 11H, in the secondary etching process, the inorganic film IOF may be removed to form the partition wall PW including the first partition wall layer L1, the organic film OF, and the second partition wall layer L2. The first partition wall layer L1 may have a shape corresponding to the opening IOP.

Referring to FIGS. 11F and 11H together, a portion of the first preliminary partition wall layer PL1 disposed on the preliminary pixel defining layer PDL-1 exposed through the opening IOP may form the first portion P1 (see FIG. 7B) of the first partition wall layer L1. A portion of the first preliminary partition wall layer PL1 disposed on the inner surface of the inorganic film IOF defining the opening IOP may form the first side portion S1 (see FIG. 7B) of the first partition wall layer L1. A portion of the first preliminary partition wall layer PL1 disposed on the top surface of the inorganic film IOF may form a second portion P2 (sec FIG. 7B) of the first partition wall layer L1.

In the secondary etching process, the inorganic film IOF may be removed to expose the first outer surface OS1 of the first side portion S1 (see FIG. 7B). In the secondary etching process, the first and second preliminary partition wall layers PL1 and PL2 may be maintained without being etched, and thus, each of the second outer surface OS2 of the second portion P2 (see FIG. 7B) of the first partition wall layer L1 and the third outer surface OS3 of the second partition wall layer L2 may have a shape that protrudes toward a center of each of the anodes AE1, AE2, and AE3 when compared to the first outer surface OS1.

As illustrated in FIG. 11H, after the process of secondarily etching the inorganic film IOF, partition walls PW in which partition wall openings OP1-P, OP2-P, and OP3-P are defined may be formed. The partition wall openings OP1-P, OP2-P, and OP3-P may include a first partition wall opening OP1-P, a second partition wall opening OP2-P, and a third partition wall opening OP3-P. The first partition wall opening OP1-P may overlap the first anode AE1, the second partition wall opening OP2-P may overlap the second anode AE2, and the third partition wall opening OP3-P may overlap the third anode AE3.

Each of the partition wall openings OP1-P, OP2-P, and OP3-P may include a first area A1 and a second area A2, which are sequentially disposed in the third direction DR3 that is a thickness direction. The first partition wall layer L1 may include a first outer surface OS1 of a first side portion S1 (see FIG. 7B) defining the first areas A1 of the first to third partition wall openings OP1-P, OP2-P, and OP3-P and a second outer surface OS2 of the first portion P1 defining portions of the second areas A2. The second partition wall layer L2 may include the third outer surface OS3 defining remaining portions of the second areas A2 of the first to third partition wall openings OP1-P, OP2-P, and OP3-P.

Referring to FIG. 11I, the method for manufacturing the display panel according to this embodiment may include a process of etching a pixel defining layer PDL and a process of etching preliminary sacrificial patterns SP1-I, SP2-I, and SP3-I (see FIG. 11H). The etching process of the pixel defining layer PDL may be performed using a dry etching method and may be etched using the first photoresist pattern PR1 and the partition wall PW as masks. Light-emitting openings OP1-E, OP2-E, and OP3-E corresponding to the partition wall openings OP1-P, OP2-P, and OP3-P may be formed in the pixel defining layer PDL. The light-emitting openings OP1-E, OP2-E, and OP3-E may include a first light-emitting opening OP1-E, a second light-emitting opening OP2-E, and a third light-emitting opening OP3-E.

The etching process of the preliminary sacrificial patterns SP1-I, SP2-I, and SP3-I may be performed by a wet etching method and may be etched using the first photoresist pattern PR1 and the partition wall PW as masks. Sacrificial openings OP1-S, OP2-S, and OP3-S overlapping the first to third light-emitting openings OP1-E, OP2-E, and OP3-E may be formed in sacrificial patterns SP1, SP2, and SP3 formed by etching the preliminary sacrificial patterns SP1-I, SP2-I, and SP3-I.

The sacrificial patterns SP1, SP2, and SP3 may include a first sacrificial pattern SP1, a second sacrificial pattern SP2, and a third sacrificial pattern SP3. The first sacrificial opening OP1-S overlapping the first light-emitting opening OP1-E may be formed in the first sacrificial pattern SP1, the second sacrificial opening OP2-S overlapping the second light-emitting opening OP2-E may be formed in the second sacrificial pattern SP2, and the third sacrificial opening OP3-S overlapping the third light-emitting opening OP3-E may be formed in the third sacrificial pattern SP3. At least a portion of the first anode AE1 may be exposed from the first sacrificial pattern SP1 and the pixel defining layer PDL by the first sacrificial opening OP1-S and the first light-emitting opening OP1-E. At least a portion of the second anode AE2 may be exposed from the second sacrificial pattern SP2 and the pixel defining layer PDL by the second sacrificial opening OP2-S and the second light-emitting opening OP2-E. At least a portion of the third anode AE3 may be exposed from the third sacrificial pattern SP3 and the pixel defining layer PDL by the third sacrificial opening OP3-S and the third light-emitting opening OP3-E.

The etching process of the sacrificial patterns SP1, SP2, and SP3 may be performed under an environment in which etching selectivity between the sacrificial patterns SP1, SP2, and SP3 and the anodes AE1, AE2, and AE3 is high, and thus, the anodes AE1, AE2, and AE3 may be prevented from being etched together. For example, since the sacrificial patterns SP1, SP2, and SP3 having a higher etch rate than the anodes AE1, AE2, and AE3 are disposed between the pixel defining layer PDL and the anodes AE1, AE2, and AE3, the anodes AE1, AE2, and AE3 may be prevented from being etched together and damaged during the etching process.

Referring to FIG. 11J, the method for manufacturing the display panel according to the embodiment may include, after removing the first photoresist pattern PR1 (FIG. 11I), a process of sequentially forming a first light-emitting pattern EP1 and a first cathode CE1 on the first anode AE1 within the first partition wall opening OP1-P to form a first light-emitting element ED1. The method for manufacturing the display panel according to an embodiment may further include a process of forming a first capping pattern CPI on the first light-emitting element ED1. The first capping pattern CPI may be formed to be disposed within the first partition wall opening OP1-P.

In the process of forming the first light-emitting element ED1, a first preliminary dummy layer DMP1-I may be formed on the partition wall PW. The first preliminary dummy layer DMP1-I, the first light-emitting element ED1, and the first capping pattern CPI may be formed through a same process. The first preliminary dummy layer DMP1-I may be formed on the partition wall PW and in the second and third partition wall openings OP2-P and OP3-P.

The first preliminary dummy layer DMP1-I may include a first-1 dummy layer D1-1I, a second-1 dummy layer D2-1I, and a third-1 dummy layer D3-1I. The first-1 dummy layer D1-1I and the first emission pattern EP1 may be formed through a same process, the second-1 dummy layer D2-1I and the first cathode CE1 may be formed through a same process, the third-1 dummy layer D3-1I and the first capping pattern CPI may be formed through a same process. The first preliminary dummy layer DMP1-I may be formed to be separated from the first light-emitting element ED1 and the first capping pattern CPI by the partition wall PW forming the tip part.

Referring to FIG. 11K, the method for manufacturing the display panel according to an embodiment of the disclosure may include, after forming the first light-emitting element ED1, a process of forming a preliminary lower encapsulation inorganic pattern LIL-I covering the first light-emitting element ED1.

The preliminary lower encapsulation inorganic pattern LIL-I may cover the first light-emitting element ED1 and also may cover the first preliminary dummy layer DMP1-I. A portion of the first preliminary dummy layer DMP1-I may be disposed within the first partition wall opening OP1-P. The first preliminary dummy layer DMP1-I may contact a top surface of the first capping pattern CPI and a top surface of the third-1 dummy layer D3-1I.

Referring to FIGS. 11K and 11L, the method for manufacturing the display panel according to an embodiment may include a process of patterning the preliminary lower encapsulation inorganic pattern LIL-I and the first preliminary dummy layer DMP1-I. The process of patterning the preliminary lower encapsulation inorganic pattern LIL-I and the first preliminary dummy layer DMP1-I may include a process of forming a second photoresist pattern PR2, a process of patterning the preliminary lower encapsulation inorganic pattern LIL-I to form a lower encapsulation inorganic pattern LIL, and a process of patterning the first preliminary dummy layer DMP1-I to form the dummy patterns D1.

In the process of forming the second photoresist pattern PR2, the second photoresist pattern PR2 may be formed by patterning a second preliminary photoresist layer using a photo mask after forming the second preliminary photoresist layer. Due to the patterning process, the second photoresist pattern PR2 may be formed in a pattern shape corresponding to the first light-emitting opening OP1-E.

In the process of patterning the preliminary lower encapsulation inorganic pattern LIL-I, a portion of the preliminary lower encapsulation inorganic pattern LIL-I, which does not overlap the second photoresist pattern PR2, may be removed by dry-etching the preliminary lower encapsulation inorganic pattern LIL-I. For example, a portion of the preliminary lower encapsulation inorganic pattern LIL-I, which does not overlap the first anode AE1, may be patterned to be removed. A first lower encapsulation inorganic pattern LIL1 overlapping the first light-emitting opening OP1-E may be formed from the patterned preliminary lower encapsulation inorganic pattern LIL-I.

In the process of patterning the first preliminary dummy layer DMP1-I, the first-1 dummy layer D1-1I, the second-1 dummy layer D2-1I, and the third-1 dummy layer D3-1I may be dry etched to remove a portion of each of the first-1 dummy layer D1-1I, the second-1 dummy layer D2-1I, and the third-1 dummy layer D3-1I, which does not overlap the second photoresist pattern PR2. For example, a portion of each of the first-1 dummy layer D1-1I, the second-1 dummy layer D2-1I, and the third-1 dummy layer D3-1I, which does not overlap the first anode AE1, may be patterned to be removed. First-1, second-1, and third-1 dummy patterns D11, D21, and D31 overlapping the first light-emitting opening OP1-E may be formed from the patterned first-1, second-1, and third-1 dummy layers D1-1I, D2-1I, and D3-1I. Each of the first-1, second-1, and third-1 dummy patterns D11, D21, and D31 may have a closed-line shape surrounding the corresponding emission area PXA (see FIG. 6) on a plane.

The process of patterning the first preliminary dummy layer DMP1-I may further include a process of wet-etching the first-1, second-1, and third-1 dummy layers D1-1I, D2-1I, and D3-1I after the process of dry-etching the first-1, second-1, and third-1 dummy layers D1-1I, D2-1I, and D3-1I.

In the process of patterning the first preliminary dummy layer DMP1-I, a portion of the first preliminary dummy layer DMP1-I, which does not overlap the first anode AE1, may be patterned to be removed. The first preliminary dummy layer DMP1-I formed in the second and third partition wall openings OP2-P and OP3-P may be removed through the patterning process. The first to third dummy layers D1-1I, D2-1I, and D3-1I formed on the partition wall PW, which do not overlap the first light-emitting opening OP1-E, may be removed through the patterning process. A first light-emitting pattern EP1 and a first cathode CE1 overlapping the first light-emitting opening OP1-E may be formed from the patterned first preliminary dummy layer DMP1-I. After the patterning process, the first anode AE1, the first light-emitting pattern EP1, and the first cathode CE1 formed in the first light-emitting opening OP1-E and the first partition wall opening OP1-P may constitute the first light-emitting element ED1.

Referring to FIG. 11M, the method for manufacturing the display panel according to an embodiment of the disclosure may include a process of forming a second light-emitting element ED2 and a third light-emitting element ED3. After removing the second photoresist pattern PR2 (see FIG. 11L), the second light-emitting element ED2 and the third light-emitting element ED3 may be sequentially formed. The process of forming the second light-emitting element ED2 and the third light-emitting element ED3 may be substantially the same as the process of forming the first light-emitting element ED1 described with reference to FIGS. 11J to 11L. Therefore, a display panel DP including the first to third light-emitting elements ED1, ED2, and ED3 corresponding to the emission areas PXA-R, PXA-G, and PXA-B illustrated in FIG. 7A, the first to third dummy patterns D1, D2, and D3, and the first to third lower encapsulation inorganic patterns LIL1, LIL2, and LIL3 may be formed.

Although not shown, in the method for manufacturing the display panel according to an embodiment, the process of forming the organic film OF may be omitted. In the method for manufacturing the display panel according to an embodiment, the process of forming the organic film OF may be omitted, and the process of forming the second preliminary partition wall layer PL2 may be immediately performed after the process of forming the first preliminary partition wall layer PL1. In this case, the partition wall formed in the process (S600) of forming the partition wall and the partition wall PW described in FIG. 9B may have a same shape.

The display panel according to the embodiment may have an improved transmittance of the optical signal to improve the display quality. The electronic apparatus according to the embodiment may include the display panel having an improved transmittance to improve the reliability. The method for manufacturing the display panel according to the embodiment may provide the method for manufacturing the display panel having an improved transmittance.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a base layer;
a pixel defining layer which is disposed on the base layer and in which a light-emitting opening is defined;
a partition wall which is disposed on the pixel defining layer and in which a partition wall opening corresponding to the light-emitting opening is defined; and
a light-emitting element comprising an anode, an intermediate layer, and a cathode that is in contact with the partition wall, the light-emitting element being disposed in the partition wall opening, wherein
the partition wall comprises:
a first partition wall layer disposed on the pixel defining layer and comprising transparent conductive oxide; and
a second partition wall layer disposed on the first partition wall layer and comprising a metal or silicon-based compound, and
the first partition wall layer comprises:
a first portion disposed on the pixel defining layer;
a second portion spaced apart from the pixel defining layer and having a height difference with respect to the first portion; and
a first side portion that connects the first portion and the second portion.

2. The display panel of claim 1, wherein
the partition wall opening comprises:
a first area in which the light-emitting element is disposed; and
a second area having a width less than a width of the first area,
the first side portion of the first partition wall layer comprises a first outer surface that defines the first area, and
the second portion of the first partition wall layer comprises a second outer surface that defines the second area.

3. The display panel of claim 1, wherein the cathode is in contact with the first side portion of the first partition wall layer.

4. The display panel of claim 1, wherein the partition wall further comprises an organic film disposed between the first partition wall layer and the second partition wall layer.

5. The display panel of claim 4, wherein the first portion of the first partition wall layer is directly disposed on the pixel defining layer.

6. The display panel of claim 4, wherein
a gap defined by the first portion, the first side portion, and a portion of the second partition wall layer is defined in the partition wall, and
the organic film is disposed to be filled into the gap.

7. The display panel of claim 4, wherein the second partition wall layer is disposed on the first portion and the organic film.

8. The display panel of claim 1, wherein an outer surface of the second portion and an outer surface of the second partition wall layer define an alignment surface.

9. The display panel of claim 1, wherein the second partition wall layer is directly disposed on the first partition wall layer.

10. The display panel of claim 9, wherein the second partition wall layer comprises:
a third portion disposed on the first portion;
a fourth portion spaced apart from the first portion and having a height difference with respect to the third portion; and
a second side portion that connects the third portion to the fourth portion.

11. The display panel of claim 1, wherein the first partition wall layer comprises at least one of indium tin oxide, indium zinc oxide, zinc oxide, indium zinc tin oxide, and indium oxide.

12. The display panel of claim 1, wherein the second partition wall layer comprises at least one of silicon oxide, silicon nitride, and silicon oxynitride.

13. The display panel of claim 1, wherein
each of the first portion and the second portion has a thickness of about 1,000 Å or more and about 2,000 Å or less, and
the second partition wall layer has a thickness of about 1,000 Å or more and about 2,000 Å or less.

14. The display panel of claim 1, further comprising:
a sacrificial pattern which is disposed between the anode and the pixel defining layer and in which a sacrificial opening overlapping the light-emitting opening is defined.

15. The display panel of claim 1, further comprising:
a thin film encapsulation layer disposed on the light-emitting element and comprising a plurality of thin films,
wherein the thin film encapsulation layer comprises an encapsulation inorganic pattern which covers the light-emitting element and of which a portion is in contact with the partition wall.

16. An electronic apparatus comprising:
a display device comprising:
a display area comprising a first area through which an optical signal passes, and a second area adjacent to the first area; and
a non-display area adjacent to the display area; and
an electronic module disposed below the display device to overlap the first area and receiving the optical signal, wherein
the display device comprises:
a base layer;
a partition wall which is disposed on the base layer and in which a partition wall opening is defined; and
a light-emitting element comprising an anode, an intermediate layer, and a cathode that is in contact with the partition wall, the light-emitting element being disposed in the partition wall opening, and
the partition wall comprises:
a first partition wall layer disposed on the base layer and comprising transparent conductive oxide;
a second partition wall layer disposed on the first partition wall layer and comprising a metal or silicon-based compound; and
an organic film disposed between the first partition wall layer and the second partition wall layer.

17. A method for manufacturing a display panel, the method comprising:
providing a preliminary display panel comprising a base layer, an anode disposed on the base layer, and a preliminary pixel defining layer disposed on the base layer to cover the anode;
forming an inorganic film in which an opening through which a top surface of the preliminary pixel defining layer is exposed is defined, on the preliminary display panel;
forming a first preliminary partition wall layer that overlaps at least the opening and comprises transparent conductive oxide;
forming a second preliminary partition wall layer comprising a metal or silicon-based compound on the first preliminary partition wall layer;
forming a photoresist pattern overlapping the opening on the second preliminary partition wall layer;
etching the inorganic film, the first preliminary partition wall layer, and the second preliminary partition wall layer using the photoresist pattern as a mask to form a partition wall in which a partition wall opening overlapping the anode is defined; and
forming a light-emitting pattern and a cathode that is in contact with the partition wall in the partition wall opening.

18. The method of claim 17, wherein
the forming of the partition wall comprises:
primarily etching the inorganic film, the first preliminary partition wall layer, and the second preliminary partition wall layer; and
secondarily etching the inorganic film, and in the secondarily etching of the inorganic film, the inorganic film is removed.

19. The method of claim 17, wherein
in the forming of the partition wall, a first partition wall layer and a second partition wall layer are formed,
the first partition wall layer comprises:
a first portion adjacent to the base layer;
a second portion spaced apart from the base layer and having a height difference with respect to the first portion; and
a first side portion connecting the first portion to the second portion, and
an outer surface of the second portion is more adjacent to a center of the anode than an outer surface of the first side portion.

20. The method of claim 17, wherein
in the forming of the first preliminary partition wall layer, a groove overlapping the opening is formed in the first preliminary partition wall layer, and
the method further comprises, before the forming of the second preliminary partition wall layer, providing an organic material in the groove to form an inorganic film.
